(19) United States
(12) Patent Application Publication
(10) Pub. No.: US 2022/0262978 A1
(43) Pub. Date: Aug. 18, 2022

(54) NANOWIRE DEVICE

(71) Applicants: CRAYONANO AS, Tronatheim (NO); NORWEGIAN UNIVERSITY OF SCIENCE AND TECHNOLOGY (NTNU), Tronaheim (NO)

(72) Inventors: Mazid MUNSHI, Cambridgeshire (GB); Helge WEMAN, Ecublens (CH); Dasa L. DHEERAJ, Singapore (SG); Bjorn-Ove M. FIMLAND, Trondheim (NO); Leidulv VIGEN, Trondheim (NO); David BARRIET, Trondheim (NO)

(21) Appl. No.: 17/627,290

(22) PCT Filed: Jul. 16, 2020
(86) PCT No.: PCT/EP2020/070228

§ 371 Date: Jan. 14, 2022

(30) Foreign Application Priority Data
Jul. 16, 2019 (GB) 1910170.8

(51) Int. Cl. H01L 33/08; H01L 31/0304; H01L 31/0352; H01L 31/0392; H01L 31/18; H01L 33/00; H01L 33/06; H01L 33/12; H01L 33/24; H01L 33/32

(52) U.S. Cl. CPC H01L 33/08; H01L 31/03048; H01L 31/035236; H01L 31/035281; H01L 31/0392; H01L 33/32; H01L 31/1852; H01L 33/007; H01L 33/06; H01L 33/12; H01L 33/24; H01L 31/1848

(57) ABSTRACT

A composition of matter comprising: a graphene layer carried directly on a sapphire, Si, SiC, Ga₂O₃ or group III-V semiconductor substrate; wherein a plurality of holes are present through said graphene layer; and wherein a plurality of nanowires or nanopyramids are grown from said substrate in said holes, said nanowires or nanopyramids comprising at least one semiconducting group III-V compound.

This invention concerns the growth and fabrication of optoelectronic devices using a graphene layer as a transparent and/or conducting electrode on a substrate. The graphene layer can be provided with a masking layer and both layers are hole patterned to allow positioned semiconductor nanowire or nanopyramid growth from the substrate. The invention also relates to compositions with an intermediate layer between the substrate and graphene layer, which can influence/promote the growth of semiconductor structures on the hole-patterned graphene via remote epitaxy. The invention also relates to compositions of matter having a semiconductor substrate to influence/promote remote epitaxy. The compositions of matter that are formed can be used in an optoelectronic device such as an LED or photodetector.

### BACKGROUND

Over recent years, the interest in semiconductor nanowires has intensified as nanotechnology becomes an important engineering discipline. Nanowires, which are also referred to as nanowhiskers, nanorods, nanopillars, nanocolumns, etc. by some authors, have found important applications in a variety of electrical devices such as sensors, solar cells and LED's.

Conventionally, semiconductor nanowires have been grown on a substrate identical to the nanowire itself (homoepitaxial growth). Thus, GaAs nanowires are grown on GaAs substrates, GaN nanowires are grown on GaN substrates, and so on. This, of course, ensures that there is a lattice match between the crystal structure of the substrate and the crystal structure of the growing nanowire. In case of heteroepitaxial growth, GaN nanowires are grown on sapphire or silicon substrates and so on. Both substrate and nanowire can have identical crystal structures. In case of a non-conducting substrate such as sapphire, one problem is that it needs to be provided with an electrode to form a contact with the semiconductor nanowires.

Graphene has been suggested as a possible electrode. As an alternative to growth on a semiconductor substrate, the growth of nanowires (NWs) on graphene is known where the graphene acts as an electrode. In WO2012/080252, there is a discussion of the growth of semiconducting nanowires on graphene substrates. WO2013/104723 concerns improvements on the WO2012/080252 disclosure in which a graphene top contact is employed on NWs grown on graphene. In these cases however nanowire growth occurs on the graphene layer and not on the support underneath.

In order to position the nanowires, it is known to use a mask with a hole array pattern where nanowires are allowed to grow only/mainly in the hole-patterned area. The mask can also promote NW growth in a direction perpendicular to the substrate. Typically, a silica layer is applied to a substrate and etched to create holes in a desired pattern. Nanowires then grow only/mainly at the location of the holes. Mask layers have been used in conjunction with nanowire growth on graphene (see WO2013/104723).

The present inventors propose to use a graphene layer as a transparent and/or conductive layer on a substrate. More importantly, in a particular aspect of the invention, that graphene layer is also covered with a masking layer before hole patterning and the growth of NWs or nanopyramids (NPs).

The inventors have appreciated that a graphene layer can be etched to form holes for positioned NW or NP growth from the substrate or from an intermediate layer below the graphene. Surprisingly, the hole-patterned graphene layer is still able to act as an electrode for the NW or NPs despite these growing from the substrate (or intermediate layer) and not on the graphene layer itself. It is envisaged that as contact is made between the edges of the graphene layer and the edges of the NWs or NPs that an electrical contact occurs.

The inventors have also realised that the use of an intermediate layer between the graphene and substrate can lead to advantages arising from remote epitaxial effects. Any additional nanostructures that have grown on top of the graphene directly, i.e. not in the holes, can also be epitaxial with the intermediate layer beneath the graphene through remote epitaxy. This can lead to structural and optical/electrical benefits, especially when the NWs/NPs are grown to coalesce. In such an aspect, there is typically no masking layer on top of the graphene. Such a beneficial effect can also be achieved by selection of an appropriate semiconductor substrate.

It has previously been reported in WO2017/044577 that graphene can act as a mask but the teaching of this reference is that after semiconductor growth, the 2D graphene layer should be removed. There is no appreciation that the graphene layer might act as an electrode for the nanowires/nanopyramids despite these growing from the substrate.

In Applied Physics Letters 108, 103105 (2016) there is a suggestion to grow GaN semiconductor mesas from a SiC substrate having a graphene mask and a comment that the graphene might act as a back low-dissipative electrode. However, the growth occurs in the absence of any additional masking layer and the graphene layer is grown via sublimation of SiC. Moreover, there is no disclosure of an intermediate layer which may influence the growth of nanostructures that may take place on the graphene mask by remote epitaxy.

The presence of the additional masking layer may be important for various reasons. The masking layer can be deposited after deposition of the graphene layer, and therefore protects the graphene surface. Any contamination or defects in the graphene layer results in degradation of its electronic properties.

The masking layer may also eliminate the risk of unwanted nanowire/nanostructure growth directly on graphene layer. The presence of a masking layer may prevent electrical short circuits, especially in the context of nanowire/nanopyramid core-shell devices. The masking layer may also enhance selectivity towards growth on the substrate through the holes in the mask.

### SUMMARY OF INVENTION

Thus, viewed from one aspect the invention provides a composition of matter comprising:

a sapphire, Si, SiC, Ga₂O₃ or group III-V semiconductor substrate;

an intermediate group III-V semiconductor layer directly on top of said substrate;

a graphene layer directly on top of said intermediate layer;

wherein a plurality of holes are present through said graphene layer; and wherein

a plurality of nanowires or nanopyramids are grown from said intermediate layer in said holes, said nanowires or nanopyramids comprising at least one semiconducting group III-V compound.

Viewed from another aspect the invention provides a composition of matter comprising:

a graphene layer carried directly on a sapphire, Si, SiC, Ga₂O₃ or group III-V semiconductor substrate;

wherein a plurality of holes are present through said graphene layer; and wherein

a plurality of nanowires or nanopyramids are grown from said substrate in said holes, said nanowires or nanopyramids comprising at least one semiconducting group III-V compound

Viewed from another aspect the invention provides a composition of matter comprising:

a graphene layer carried directly on a sapphire, Si, SiC, Ga₂O₃ or group III-V semiconductor substrate; and

an oxide or nitride masking layer directly on top of said graphene layer;

wherein a plurality of holes are present through said graphene layer and through said masking layer to said substrate; and wherein

a plurality of nanowires or nanopyramids are grown from said substrate in said holes, said nanowires or nanopyramids comprising at least one semiconducting group III-V compound.

Viewed from another aspect, the invention provides a composition of matter comprising:

a graphene layer carried directly on a sapphire, Si, SiC, Ga₂O₃ or group III-V semiconductor substrate; and

an oxide, nitride or fluoride masking layer directly on top of said graphene layer;

wherein a plurality of holes are present through said graphene layer and through said masking layer to said substrate; and wherein

a plurality of nanowires or nanopyramids are grown from said substrate in said holes, said nanowires or nanopyramids comprising at least one semiconducting group III-V compound.

Viewed from another aspect the invention provides a process comprising:

(I) obtaining a composition of matter in which a graphene layer is carried directly on a group III-V intermediate layer, wherein said intermediate layer is carried directly on a sapphire, Si, SiC, Ga₂O₃ or group III-V semiconductor substrate;

(II) etching a plurality of holes through said graphene layer; and

(III) growing a plurality of nanowires or nanopyramids from said intermediate layer in said holes, said nanowires or nanopyramids comprising at least one semiconducting group III-V compound.

Viewed from another aspect, the invention provides a process comprising:

(I) providing a graphene layer carried on a sapphire, Si, SiC, Ga₂O₃ or group III-V semiconductor substrate;

(II) depositing an oxide, nitride or fluoride masking layer on said graphene layer;

(III) introducing a plurality of holes in said masking layer and graphene layer, said holes penetrating through to said substrate; and

(IV) growing a plurality of semiconducting group III-V nanowires or nanopyramids in the holes, preferably via molecular beam epitaxy or metal organic vapour phase epitaxy.

Viewed from another aspect, the invention provides a process comprising:

(I) obtaining a composition of matter in which a graphene layer is carried directly on a sapphire, Si, SiC, Ga₂O₃ or group III-V semiconductor substrate;

(II) etching a plurality of holes through said graphene layer; and

(III) growing a plurality of nanowires or nanopyramids from said substrate in said holes, said nanowires or nanopyramids comprising at least one semiconducting group III-V compound.

Viewed from another aspect the invention provides a process comprising:

(I) providing a graphene layer directly carried on a sapphire, Si, SiC, Ga₂O₃ or group III-V semiconductor substrate;

(II) depositing an oxide or nitride masking layer directly on said graphene layer;

(III) introducing a plurality of holes in said masking layer and graphene layer, said holes penetrating through to said substrate; and

(IV) growing a plurality of semiconducting group III-V nanowires or nanopyramids in said holes, preferably via a molecular beam epitaxy or metal organic vapour phase epitaxy.

Viewed from a further aspect the invention provides a composition of matter comprising:

a graphene layer carried directly on a sapphire, Si, SiC, Ga₂O₃ or group III-V semiconductor substrate; and

an oxide or nitride masking layer directly on top of said graphene layer;

wherein a plurality of holes are present through said graphene layer and through said masking layer to said substrate,

wherein the holes in the masking layer are larger than the holes in the graphene layer so that a portion of the graphene layer is exposed under the masking layer; and wherein

a plurality of nanowires or nanopyramids are grown from said substrate in said holes, said nanowires or nanopyramids comprising at least one semiconducting group III-V compound.

Viewed from another aspect the invention provides a product obtained by a process as hereinbefore defined.

Viewed from another aspect the invention provides a device, such as an electronic device, comprising a composition as hereinbefore defined, e.g. a solar cell, light emitting device or photodetector.

Viewed from another aspect the invention provides a composition of matter comprising:

a graphene layer carried directly on a sapphire, Si, SiC, Ga₂O₃ or group III-V semiconductor substrate;

wherein a plurality of holes are present through said graphene layer; and wherein

a plurality of nanowires or nanopyramids are grown from said substrate in said holes, said nanowires or nanopyramids comprising at least one semiconducting group III-V compound.

### Definitions

By a group III-V compound semiconductor is meant one comprising at least one element from group III and at least one element from group V. There may be more than one element present from each group, e.g. InGaAs, AlGaN (i.e. a ternary compound), AlInGaN (i.e. a quaternary compound) and so on. The term semiconducting nanowire or nanopyramid is meant nanowire or nanopyramid made of semiconducting materials from group III-V elements.

The term nanowire is used herein to describe a solid, wire-like structure of nanometer dimensions. Nanowires preferably have an even diameter throughout the majority of the nanowire, e.g. at least 75% of its length. The term nanowire is intended to cover the use of nanorods, nanopillars, nanocolumns or nanowhiskers some of which may have tapered end structures. The nanowires can be said to be in essentially in one-dimensional form with nanometer dimensions in their width or diameter and their length typically in the range of a few 100 nm to a few μm. Ideally the nanowire diameter is not greater than 500 nm. Ideally the nanowire diameter is between 50 and 500 nm, however, the diameter can exceed few micrometers (called microwires).

Ideally, the diameter at the base of the nanowire and at the top of the nanowire should remain about the same (e.g. within 20% of each other).

The term nanopyramid refers to a solid pyramidal type structure. The term pyramidal is used herein to define a structure with a base whose sides taper to a single point generally above the centre of the base. It will be appreciated that the single vertex point may appear chamfered, e.g. such that the pyramid has a flat top Typically, the chamfered portion is equivalent to less than 50%, e.g. less than 40%, e.g. less than 30%, e.g. less than 20%, e.g. less than 10%, e.g. less than 5% of the total length of the nanopyramid edge. The nanopyramids may have multiple faces, such as 3 to 8 faces, or 4 to 7 faces. Thus, the base of the nanopyramids might be a square, pentagonal, hexagonal, heptagonal, octagonal and so on. The pyramid is formed as the faces taper from the base to a central point (forming therefore triangular faces). The triangular faces are normally terminated with (1-101) or (1-102) planes. The triangular side surfaces with (1-101) facets could either converge to a single point at the tip or could form a new facets ((1-102) planes) before converging at the tip. In some cases, the nanopyramids are truncated with its top terminated with {0001} planes. The base itself may comprise a portion of even cross-section before tapering to form a pyramidal structure begins. The thickness of the base may therefore be up to 500 nm, e.g. up to 200 nm, such as 50 nm.

The base of the nanopyramids can be 50 and 500 nm in diameter across its widest point. In another embodiment, the base of the nanopyramids can be 200 nm to one micrometer in diameter across its widest point. The height of the nanopyramids may be 200 nm to a few micrometers, such as 400 nm to 1 micrometer in length.

It will be appreciated that the substrate comprises a plurality of nanowires or nanopyramids. This may be called an array of nanowires or nanopyramids.

Graphene layers are films composed of single or multiple layers of graphene or its derivatives. The term graphene refers to a planar sheet of sp²-bonded carbon atoms in a honeycomb crystal structure. Whilst it is preferred to use graphene it is also possible to use derivatives of graphene such as those with surface modification. For example, the hydrogen atoms can be attached to the graphene surface to form graphane. Graphene with oxygen atoms attached to the surface along with carbon and hydrogen atoms is called as graphene oxide. The surface modification can be also possible by chemical doping or oxygen/hydrogen or nitrogen plasma treatment.

The term epitaxy comes from the Greek roots epi, meaning “above”, and taxis, meaning “in ordered manner”. The atomic arrangement of the nanowire or nanopyramid is based on the crystallographic structure of the substrate. It is a term well used in this art. Epitaxial growth means herein the growth on the substrate of a nanowire or nanopyramid that mimics the orientation of the substrate.

Selective area growth (SAG) is the most promising method for growing positioned nanowires or nanopyramids. This method is different from the self-assembled metal catalyst assisted vapour-liquid-solid (VLS) method, in which metal catalyst act as nucleation sites at random locations for the growth of nanowires or nanopyramids. Another self-assembled method to grow nanowires or nanopyramids is catalyst-free method, where nanowires or nanopyramids are nucleated in random positions. These methods yield huge fluctuations in the length and diameter of the nanowires and the height and width of nanopyramids. Positioned nanowires or nanopyramids can also be grown by the catalyst-assisted method.

The SAG method or the catalyst-assisted positioned growth method typically requires a mask with nano-hole patterns on the substrate. The nanowires or nanopyramids nucleate mainly in the holes of the patterned mask on the substrate. This yields uniform size and pre-defined position of the nanowires or nanopyramids.

The masking layer refers to the mask material that is directly deposited on the graphene layer. The mask material should ideally not absorb emitted light (which could be visible, UV-A, UV-B or UV-C) in the case of an LED or not absorb the entering light of interest in the case of a photodetector. Usually, the mask should also be electrically non-conductive. The mask could contain one or more than one material, which include Al₂O₃, SiO₂, Si₃N₄, MoO₂ TiO₂, W₂O₃, HfO₂, h-BN, AlN, MgF₂, CaF₂ and so on.

Subsequently, the hole patterns in the mask material can be prepared using lithography such as electron beam lithography, nanoimprint lithography and so on, and dry or wet etching.

Molecular beam epitaxy (MBE) is a method of forming depositions on crystalline substrates. The MBE process is performed by heating a crystalline substrate in a vacuum so as to energize the substrate's lattice structure. Then, an atomic or molecular mass beam(s) is directed onto the substrate's surface. The term element used above is intended to cover application of atoms, molecules or ions of that element. When the directed atoms or molecules arrive at the substrate's surface, the directed atoms or molecules encounter the substrate's energized lattice structure or a catalyst droplet as described in detail below. Over time, the oncoming atoms form a nanowire.

Metalorganic vapour phase epitaxy (MOVPE) also called as metalorganic chemical vapour deposition (MOCVD) is an alternative method to MBE for forming depositions on crystalline substrates. In case of MOVPE, the deposition material is supplied in the form of metalorganic precursors, which on reaching the high temperature substrate decomposes leaving atoms on the substrate surface. In addition, this method requires a carrier gas (typically H₂ and/or N₂) to transport deposition materials (atoms/molecules) across the substrate surface. These atoms reacting with other atoms form an epitaxial layer on the substrate surface. Choosing the deposition parameters carefully results in the formation of a nanowire.

The term carried directly implies that the layers in question are adjacent.

### DETAILED DESCRIPTION OF INVENTION

This invention concerns the growth of positioned nanowires or nanopyramids through the holes of a graphene layer. The semiconductor nanowire or nanopyramid array comprises a plurality of nanowires or nanopyramids grown epitaxially from the substrate, or from an intermediate layer positioned between the substrate and the graphene layer.

In a particular aspect, this invention concerns the use of a graphene layer in combination with an upper/additional masking layer as a mask on a substrate for positioned nanowire or nanopyramid growth. The graphene layer is transparent, conductive and flexible. The semiconductor nanowire or nanopyramid array comprises a plurality of nanowires or nanopyramids grown epitaxially from said substrate. If the composition comprises an intermediate layer between the substrate and the graphene layer, the nanowires or nanopyramids are grown epitaxially from the intermediate layer.

Having a nanowire or nanopyramid grown epitaxially provides homogeneity to the formed material which may enhance various end properties, e.g. structural, mechanical, optical or electrical properties.

Epitaxial nanowires or nanopyramids may be grown from gaseous, liquid or solid precursors. Because the substrate or intermediate layer acts as a seed crystal, the deposited nanowire or nanopyramid can take on a lattice structure and orientation similar to those of the substrate or intermediate layer. Epitaxy is different from other thin-film deposition methods which deposit polycrystalline or amorphous films, even on single-crystal substrates.

### Graphene Layer

As used herein, the term graphene refers to a planar sheet of sp²-bonded carbon atoms that are densely packed in a honeycomb (hexagonal) crystal lattice. This graphene layer should preferably be no more than 20 nm in thickness. Ideally, it should contain no more than 10 layers of graphene or its derivatives, preferably no more than 5 layers (which is called as a few-layered graphene), preferably no more than 4 layers of graphene, preferably no more than 3 layers of graphene, preferably 1-5 layers of graphene, preferably 1-4 layers of graphene, e.g. 2-4 layers of graphene. Especially preferably, it is a one-atom-thick planar sheet of graphene.

It is preferred if the graphene layer in general is 20 nm in thickness or less. Graphene sheets stack to form graphite with an interplanar spacing of 0.335 nm. The graphene layer preferred comprises only a few such layers and may ideally be less than 10 nm in thickness. Even more preferably, the graphene layer may be 5 nm or less in thickness, more preferably 4 nm or less in thickness, more preferably 3 nm or less in thickness, more preferably 2 nm or less in thickness Preferred thickness ranges include 0.3-10 nm, preferably 1-5 nm, 1-3 nm or 1-2 nm. Having a thin graphene layer is not only important for optical/electronic properties, but also for remote epitaxial effects (i.e. wherein the crystal orientation of a structure on top of the graphene is influenced by the crystal orientation of the intermediate layer/substrate below the graphene layer). Typically, the best results for remote epitaxy are obtained when no more than 3-4 graphene layers are used (equivalent to about 1-2 nm).

The area of the graphene layer in general is not limited. This might be as much as 0.5 mm² or more, e.g. up to 5 mm² or more such as up to 10 cm². The area of the graphene layer is thus only limited by practicalities. Graphene wafers may be 1.0 to 100 square inches, such as 2 square inches or even 50 square inches in size.

In a highly preferred embodiment, the graphene layer is single layer or multi-layer graphene grown on metal catalysts by using a chemical vapour deposition (CVD) method. Metal catalysts can be metallic films or foils made of e.g. Cu, Ni, or Pt. Transfer of the graphene layer grown on these metal catalysts to another substrate can be affected by techniques discussed in detail below. The graphene layer can also be directly grown on the substrate or on the intermediate layer. In that case, transfer process is not required. The graphene layer can also be grown on SiC substrate using thermal sublimation process and may be transferred onto a target substrate if needed. Alternatively, the substrate is a laminated graphite substrate exfoliated from Kish graphite, a single crystal of graphite, or is a highly ordered pyrolytic graphite (HOPG).

Whilst it is preferred if the graphene layer is used without modification, the surface of the graphene layer can be modified. For example, it can be treated with plasma of hydrogen, oxygen, nitrogen, NO₂ or their combinations. Oxidation of the graphene layer might enhance nanowire or nanopyramid nucleation. It may also be preferable to pre-treat the graphene layer, for example, to ensure purity before nanowire or nanopyramid growth. Treatment with a strong acid such as HF or BOE is an option.

The graphene layer may be doped to improve its electrical conductivity. As the graphene layer may be used as an electrode, it might be doped to give a better ohmic contact with the bottom part of the nanowire/nanopyramid.

The graphene layer might be washed with iso-propanol, acetone, or n-methyl-2-pyrrolidone to eliminate surface impurities.

The cleaned graphene surface can be further modified by doping. A solution of FeCl₃, AuCl₃ or GaCl₃ could be used in a doping step.

The graphene layer is well known for its superior optical, electrical, thermal and mechanical properties. They are very thin but very strong, light, flexible, and impermeable. Most importantly in the present invention they are highly electrically and thermally conducting, flexible and transparent. Crucially therefore, the graphene layer can act as an electrode to the nanowires or nanopyramids that are grown from the substrate or intermediate layer. Typically, therefore, the graphene layer is in electrical contact with at least a portion of the nanowires or nanopyramids.

### Substrate

The nanowires and nanopyramids grow from the substrate and hence it is preferred that the substrate is a crystalline substrate. Suitable substrates include sapphire, Si, SiC, Ga₂O₃, or a group III-V semiconductor substrate such as GaN, AlN, GaAs, nd so on. The Ga₂O₃ is preferably β-Ga₂O₃. Suitable group III-V semiconductors are those described below in context with the nanowires or nanopyramids.

Moreover, for the group III-V semiconductor option, group III options are B, Al, Ga, In, and Tl. Preferred options here are Ga, Al and In. Group V options are N, P, As, Sb. A preferred option is N. It is of course possible to use more than one element from group III and/or more than one element from group V for the substrate layer. Preferred III-V semiconductor compounds for the substrate layer include BN, AlAs, GaSb, GaP, GaN, AlN, AlGaN, AlGaInN, GaAs, InP, InN, InGaN, InGaAs, InSb, InAs, or AlGaAs. Compounds based on Al, Ga and In in combination with N are one option. The use of GaN, AlGaN, AlInGaN or AlN is highly preferred. These materials have strong ionic forces which can result in enhanced remote epitaxy (see discussion below). AlN is particularly preferred, because it not only has strong ionic forces but is also UVC transparent and therefore better suited for flip chip UVC LEDs. AlN has much stronger ionic forces than, for example, sapphire, and these aid to induce a higher yield of remote epitaxy of the group III-V island growth on graphene.

Mixtures of the above substrate materials may also be used. Particularly preferred options include sapphire, GaN, GaN/Sapphire; AlGaN, AlGaN/Sapphire; AlN/Sapphire, Si; GaN/Si; AlGaN/Si; AlN/Si, SiC; GaN/SiC; AlGaN/SiC; AlN/SiC. Highly preferred options include Ga₂O₃ or (AlₓGa₁₋ₓ)₂O₃. The combinations AlN/Sapphire, AlN/Si or AlN/SiC are particularly preferred, in particular, AlN/Sapphire. In the nomenclature above, the first compound in the grouping (i.e. the compound before the ‘/’) is typically an intermediate layer, and the second compound is the substrate beneath the intermediate layer. Intermediate layers are discussed in more detail below.

Substrates can be crystalline and may have a crystal orientation of [111], [110], or [100] perpendicular to the surface.

The use of sapphire with a crystal orientation [0001] is especially preferred.

In a particular embodiment, the use of a sapphire, SiC, Ga₂O₃ or group III-V semiconductor substrate is preferred (particularly group III-V semiconductor substrate), as this can result in remote epitaxy through the graphene layer and influence the growth of nanostructures on top of the graphene, in the case where there is no intermediate layer. In a particular embodiment, group III-V semiconductor substrates are preferred (e.g. AlN), especially where there is no intermediate layer present.

In a particular embodiment, the substrate is selected from sapphire, Si, SiC, Ga₂O₃ or a group III-V semiconductor substrate when there is an intermediate layer, or from a sapphire, SiC, Ga₂O₃ or group III-V semiconductor substrate when there is no intermediate layer (as these can lead to remote epitaxial effects).

In a particular embodiment, therefore, the invention provides a composition of matter comprising:

a substrate;

an optional intermediate group III-V semiconductor layer directly on top of said substrate;

a graphene layer directly on top of said intermediate layer if present, or on top of the substrate;

wherein a plurality of holes are present through said graphene layer; and wherein

a plurality of nanowires or nanopyramids are grown from said substrate or from said intermediate layer in said holes, said nanowires or nanopyramids comprising at least one semiconducting group III-V compound;

wherein when an intermediate layer is present, the substrate is selected from sapphire, Si, SiC, Ga₂O₃ or a group III-V semiconductor substrate, and when there is no intermediate layer, the substrate is selected from sapphire, SiC, Ga₂O₃ or a group III-V semiconductor substrate.

### Intermediate Layer/Remote Epitaxy/Nanoislands

In a particular embodiment, the substrate has an intermediate layer positioned on top of it. Such an intermediate layer is positioned between the substrate and the graphene layer. In other words, the composition comprises the substrate, the intermediate layer and the graphene layer in that order.

The intermediate layer is formed from at least one III-V compound. In case the semiconductor substrate is a group III-V semiconductor substrate, then the intermediate layer is formed from a different group III-V compound. Typically the intermediate layer is crystalline.

Group III options are B, Al, Ga, In, and Tl. Preferred options here are Ga, Al and In. Group V options are N, P, As, Sb. A preferred option is N. It is of course possible to use more than one element from group III and/or more than one element from group V for the intermediate layer. Preferred compounds for the intermediate layer include BN, AlAs, GaSb, GaP, GaN, AlN, AlGaN, AlGaInN, GaAs, InP, InN, InGaN, InGaAs, InSb, InAs, or AlGaAs. Compounds based on Al, Ga and In in combination with N are one option. The use of GaN, AlGaN, AlInGaN or AlN is highly preferred. These materials have strong ionic forces which can result in enhanced remote epitaxy (see discussion below). AlN is particularly preferred, because it not only has strong ionic forces but is also UVC transparent and therefore better suited for flip chip UVC LEDs. AlN has much stronger ionic forces than, for example, sapphire, and these aid to induce a higher yield of remote epitaxy of the group III-V island growth on graphene.

In a particular embodiment, there is a remote epitaxial relationship between the intermediate layer and the semiconductor nanostructures grown on top of the graphene layer. In another embodiment, there is a remote epitaxial relationship between the substrate and the semiconductor nanostructures grown on top of the graphene layer.

In a particular embodiment, the intermediate layer has a thickness of less than 200, preferably less than 100 nm, more preferably less than 75 nm, e.g. of around 50 nm. Suitable thickness ranges include 1-200 nm, preferably 10-100 nm, e.g. 25-75 nm.). The use of a thin intermediate layer enables remote epitaxial effects to take place without having to use an entire substrate made of expensive semiconductor material.

The oxide or nitride mask is not always completely selective and it is possible to get some nanowire/nanopyramid/nanoisland growth on top of the mask. Since this mask is typically amorphous, the nanowires/nanopyramids can be of low quality due to random nucleation with no in-plane order. Often, it can be difficult to prevent growth on top of the graphene layer outside of the holes (i.e. growth of so-called ‘nanoislands’). There is therefore a need to ensure that any group III-V structure growing on top of the graphene or mask layer is of high crystallinity. This is particularly important for cases of ‘coalescence’, i.e. where the positioned nanowires/nanopyramids growing through the holes are joined up.

Remote epitaxy is the phenomenon whereby a very thin layer of graphene is used, and nanostructures (or even thin films) can be grown epitaxially, with the crystal orientation of the nanostructures matching the underlying substrate rather than the graphene layer even if the graphene is polycrystalline. Despite, therefore, the graphene layer acting as a buffer between the substrate or intermediate layer and the nanostructures, they will still grow with a crystal direction/facet direction that reflects the substrate or intermediate layer rather than the graphene. We call this remote epitaxy. The resulting nanowire array is more regular with parallel facets even when the graphene is polycrystalline. This improves the various properties of the material.

The nanowires/nanopyramids grow such that the crystal orientation and facet orientations of said nanowires or nanopyramids are directed by the crystalline substrate/intermediate layer. Thus the crystal orientation and facet orientations are the same for all nanowires/nanopyramids.

When remote epitaxy occurs, the growing nanostructures adopt their crystal (and thus facet) orientation from the crystalline layer underneath the graphene layer. The nanostructures can be considered therefore to have parallel facets. In contrast, where nanostructures grow epitaxially from polycrystalline graphene, then the resulting nanowire facets are randomly oriented in different domains/grains, i.e., whereas the sides (facets) of hexagonal nanowires can be parallel within one graphene domain/grain, they are not parallel to but are at random orientation relative the sides (facets) of hexagonal nanowires within neighboring graphene domains/grains. Nanowires can be hexagonal or square in cross section, preferably hexagonal. Remote epitaxy occurs where all crystal and facet orientations are the same.

The use of an intermediate layer, preferably when there is no additional hole-mask on top of graphene, is a particular embodiment which can lead to higher quality growth for nanoislanding taking place on top of the graphene hole mask. In a particular embodiment, therefore, the composition comprises a graphene hole mask, optionally without any additional hole-mask on top of graphene (e.g. oxide/nitride masking layer), and with an intermediate layer, preferably AlN, between the substrate and the graphene. In a particular embodiment therefore, there is no oxide, nitride or fluoride masking layer. This setup has the benefits of 1) improving the selectivity and 2) inducing remote epitaxy for the group III-V islanding on the graphene hole-mask that often cannot be completely avoided.
This remote epitaxy results in the group III-V islanding (i.e. the nanoislands formed on the graphene) being in-plane epitaxial with the group III-V nanowires/nanopyramids so that no defects are created in the case that the nanowires/nanopyramids coalesce. In a particular embodiment, therefore, the composition of matter of the present invention comprises group III-V nanoislands nucleated by remote epitaxy on the graphene (i.e. they have not been grown on the intermediate/substrate layer through the holes in the graphene). Typically, the nanoislands are formed of the same material as the nanowires/nanopyramids. This is because nanoisland growth occurs at the same time as NW/NP growth. The definitions of group III-V materials for the NWs and NPs are thus applicable to the nanoislands. ‘Nanoislands’ covers nanopyramids, nanowires, nanomesas, and other structures, and is used herein to differentiate the structure from the nanowires/nanopyramids grown in the holes of the graphene. Preferably, the epitaxy, crystal orientation and facet orientations of said nanoislands are directed by the intermediate layer. Typically, therefore, the crystal orientation of the nanoislands matches that of the nanowires and nanopyramids (which have grown in the holes) and of the intermediate layer.
The use of remote epitaxy can lead to improved electrical/optical properties in the final device.

### Coalescence

It can be beneficial to form large area structures through coalescence of positioned nanowires/nanopyramids. Coalescence refers to the side-on joining of two or more nanostructures during growth, typically through un-avoidable merging of ‘island’ nanostructures which have been grown in between them. This results in a 2D or 3D structure. Such a coalesced structure typically resembles a corrugated (non-planar) thin film with pyramidal tips at the surface, i.e. the coalesced structure is typically ridged. In a particular embodiment, the coalesced structure is not planar. It is thus typically distinct from a planar thin film which has been grown on a substrate. For coalescence, the nanostructures must preferably have their crystal lattices in the same orientation, such that the formation of gaps and dislocations can largely be eliminated, i.e. the coalescing nanowires/nanopyramids and merging nanoislands must preferably have nearly identical epitaxial relationship with respect to the substrate/intermediate layer.
For coalescence it is preferred if there is no additional mask layer on top of the graphene, i.e. preferably no oxide/nitride/fluoride mask layer, since this is amorphous and may lead to low crystallinity in the coalesced structure.
In a particular embodiment, at least some or all of the nanowires/nanopyramids are coalesced. The coalesced structure may include nanostructures which have grown in between the nanowires/nanopyramids, on the graphene itself, e.g. nanoislands.
The use of a substrate/intermediate layer that promotes remote epitaxy through a graphene hole mask is particularly beneficial for coalescence, since not only are the crystal orientations and facet orientations of the nanowires/nanopyramids aligned with the substrate/intermediate layer, but any nanoislands formed on the graphene, i.e. outside of the holes, are also lattice matched with the substrate/intermediate layer by remote epitaxy. The nanoislands formed on the graphene can therefore form part of the coalesced structure with the nanowires/nanopyramids. Because of the remote epitaxy effect, the coalesced structure shows high crystallinity and is substantially defect free. Typically, very few or no dislocations or stacking faults are observed. Without remote-epitaxy, a defective and dead “active” region in-between the nanowires/nanopyramids would be obtained when the nanowires/nanopyramids coalesce.

### Masking Layer

A masking layer is optionally deposited on top of the graphene layer. An oxide, nitride or fluoride masking layer, preferably a metal oxide, metal nitride or metal fluoride layer such as a semimetal oxide or semimetal nitride is optionally deposited on top of the graphene layer. This can be achieved through atomic layer deposition, sputtering, e-beam and thermal evaporation connection with the deposition of the precursor layer. The oxide used is preferably based on a metal, preferably a semimetal (such as Si). The nature of the cation used in the masking layer may be Al, Si or a transition metal, especially a first 3d row transition metal (Sc—Zn).

Preferred oxides include SiO₂, MoO₂, TiO₂, Al₂O₃, W₂O₃, HfO₂. Preferred nitrides include Si₃N₄, BN (e.g. h-BN) and AN. Preferred fluorides include MgF₂ or CaF₂. Most especially, the masking layer is silicon oxide or silicon nitride.

It is within the scope of the invention for a second masking layer to be applied on top of the first masking layer, especially when Al₂O₃ is employed as a lower masking layer. Again, the materials used in this layer are oxides, fluorides or nitrides such as metal oxides, metal fluorides or nitrides of transition metals, Al or Si. The use of silica is preferred. It is preferred if the second masking layer is different from the first masking layer. The use of atomic layer deposition is appropriate to apply to that second masking layer or the same techniques described with the first masking layer, as described above, can be employed. It is however preferred if only one masking layer is present.

Each of the masking layers may be 5 to 100 nm in thickness, such as 10 to 50 nm. There may be a plurality of such layers, such as 2, 3 or 4 masking layers.

The masking layer(s) are preferably continuous and covers the graphene layer as a whole. One important feature of the masking layer is that it prevents nucleation of nanowires or nanopyramids on the graphene layer.

The masking layer should be smooth and free of defects so that nanowires or nanopyramids cannot nucleate on the masking layer. The presence therefore of a masking layer allows better selectivity. It also protects the graphene layer from damage. As the graphene layer acts as an electrode, any damage to that layer can hinder its ability to carry charge. The mask layer protects the graphene from damage during the high temperature nanowire growth process and/or during device processing. The masking layer may also be used to control the doping of the graphene layer.

The presence of a masking layer may also prevent shorting in the context of a core-shell structure. If a nanowire is grown in a hole in the masking layer and subsequently a shell is grown on said nanowire, the base of that shell will contact the masking layer. The masking layer therefore prevents the shell shorting on the graphene layer beneath. If the masking layer had been absent, then both core and shell components on the nanowire would be in electrical contact with the graphene layer and hence there risks an electrical short circuit.

### Patterning

The positioned nanowires or nanopyramids need to grow from the substrate or the intermediate layer. That means that holes need to be patterned through all layers on top of the substrate or intermediate layer present such as the masking layer and graphene layer. Making of these holes is a well-known process and can be carried out using e-beam lithography or any other known techniques. The hole patterns in the mask can be easily fabricated using conventional lithography techniques such as photo/e-beam lithography, nanoimprinting, and so on. Focussed ion beam technology may also be used in order to create a regular array of nucleation sites on the substrate surface or intermediate layer surface for the nanowire or nanopyramid growth. The holes created in the masking and seed layers can be arranged in any pattern which is desired.

The diameter of the holes is preferably up to 500 nm, such as up to 100 nm, ideally up to 20 to 200 nm. The diameter of the hole sets a maximum diameter for the size of the nanowires or nanopyramids so the hole size and nanowire or nanopyramid diameters should match. However, nanowire or nanopyramid diameter larger than the hole size could be achieved by changing the growth parameters or by adopting a core-shell nanowire or nanopyramid geometry.

The number of holes is a function of the area of the substrate (and optionally intermediate layer) and desired nanowire or nanopyramid density.

The shape of the holes is not limited. Whilst these may be circular, holes may also be in other shapes, such as triangular, rectangles, oval etc.

In one embodiment the hole etched in the masking layer is larger than the hole etched in the graphene layer below so that a portion of the graphene layer is exposed under the masking layer. For example, a larger and smaller circular hole may be etched in the masking layer and graphene layer respectively. This is potentially important as the graphene layer can make better contact with the nanowire as illustrated in FIG. 5. The nanowires that grow in the smaller holes in the graphene layer fill those holes as growth occurs. If subsequently, a shell is applied to the nanowire, the base of that shell grows on top of the graphene layer. Thus, the base of the nanowire contacts the graphene layer making a stronger electrical contact.

As the nanowires or nanopyramids begin growing within a hole, this tends to ensure that the initial growth of the nanowires or nanopyramids is substantially perpendicular to the substrate. This is a further preferred feature of the invention. One nanowire or nanopyramid preferably grows per hole.

### Growth of Nanowires or Nanopyramids

In order to prepare nanowires or nanopyramids of commercial importance, it is preferred that these grow epitaxially on the substrate (or on the intermediate layer, if present). It is also ideal if growth occurs perpendicular to the substrate (or intermediate layer) and ideally therefore in the [111] (for cubic crystal structure) or [0001] (for hexagonal crystal structure) direction.

In a growing nanopyramid, the triangular faces are normally terminated with (1-101) or (1-102) planes. The triangular side surfaces with (1-101) facets could either converge to a single point at the tip or could form new facets (1-102) planes before converging at the tip. In some cases, the nanopyramids are truncated with its top terminated with {0001} planes.

Whilst it is ideal that there is no lattice mismatch between a growing nanowire or nanopyramid and the substrate/intermediate layer, nanowires or nanopyramids can accommodate much more lattice mismatch than thin films for example. As the substrate or intermediate layer can be a group III-V semiconductor like the nanowires/nanopyramids, very low lattice mismatches are possible.

Growth of nanowires/nanopyramids can be controlled through flux ratios. Nanopyramids are encouraged, for example if high group V flux is employed.

The nanowires that are grown can be said to be in essentially in one-dimensional form with nanometer dimensions in their width or diameter and their length typically in the range of a few 100 nm to a few μm. Ideally the nanowire diameter is not greater than 500 nm. Ideally the nanowire diameter is between 50 and 500 nm; however, the diameter can exceed few micrometers (called microwires).

The nanowire grown in the present invention may therefore be from 250 nm to several micrometers in length, e.g. up to 5 micrometers. Preferably the nanowires are at least 1 micrometer in length. Where a plurality of nanowires are grown, it is preferred if they all meet these dimension requirements. Ideally, at least 90% of the nanowires grown on a substrate or intermediate layer will be at least 1 micrometer in length. Preferably substantially all the nanowires will be at least 1 micrometer in length.

Nanopyramids may be 250 nm to 1 micrometer in height, such as 400 to 800 nm in height, such as about 500 nm.

Moreover, it will be preferred if the nanowires or nanopyramids grown have the same dimensions, e.g. to within 10% of each other. Thus, at least 90% (preferably substantially all) of the nanowires or nanopyramids on a substrate/intermediate layer will preferably be of the same diameter and/or the same length (i.e. to within 10% of the diameter/length of each other). Essentially, therefore the skilled person is looking for homogeneity and nanowires or nanopyramids that are substantially the same in terms of dimensions.

The length of the nanowires or nanopyramids is often controlled by the length of time for which the growing process runs. A longer process typically leads to a (much) longer nanowire.

The nanowires or nanopyramids have typically a hexagonal cross sectional shape. The nanowire may have a cross sectional diameter of 25 nm to several micrometers (i.e. its thickness). As noted above, the diameter is ideally constant throughout the majority of the nanowire. Nanowire diameter can be controlled by the manipulation of the growth parameters such as the substrate temperature and/or the ratio of the atoms used to make the nanowire as described further below.

Moreover, the length and diameter of the nanowires or nanopyramids can be affected by the temperature at which they are formed. Higher temperatures encourage high aspect ratios (i.e. longer and/or thinner nanowires). The skilled person is able to manipulate the growing process to design nanowires or nanopyramids of desired dimensions.

The nanowires or nanopyramids of the invention are formed from at least one III-V compound. The group III-V compounds discussed herein for the nanowires or nanopyramids are also suitable for the group III-V semicondcuctor substrate.

Group III options are B, Al, Ga, In, and Tl. Preferred options here are Ga, Al and In.

Group V options are N, P, As, Sb. All are preferred.

It is of course possible to use more than one element from group III and/or more than one element from group V. Preferred compounds for nanowire or nanopyramid manufacture include AlAs, GaSb, GaP, GaN, AlN, AlGaN, AlGaInN, GaAs, InP, InN, InGaN, InGaAs, InSb, InAs, or AlGaAs. Compounds based on Al, Ga and In in combination with N are one option. The use of GaN, AlGaN, AlInGaN or AlN is highly preferred.

It is most preferred if the nanowires or nanopyramids consist of Ga, Al, In and N (along with any doping atoms as discussed below).

Whilst the use of binary materials such as GaN is possible, the use of ternary nanowires or nanopyramids in which there are two group III cations with a group V anion are preferred here, such as AlGaN. The ternary compounds may therefore be of formula XYZ wherein X is a group III element, Y is a group III different from X, and Z is a group V element. The X to Y molar ratio in XYZ is preferably 0.1 to 0.9, i.e. the formula is preferably XₓY₁₋ₓZ where subscript x is 0.1 to 0.9.

Quaternary systems might also be used and may e.g. be represented by the formula AₓB₁₋ₓC_{y}D_{1-y} where A and B are group III elements and C and D are group V elements or AₓB_{y}C_{1-x-y}D where A, B and C are group III elements and D is a group V element. Again subscripts x and y are typically 0.1 to 0.9. Other options will be clear to the skilled man.

Doping

The nanowires or nanopyramids of the invention can contain a p-n or p-i-n junction, e.g. to enable their use in LEDs. NWs or nanopyramids of the invention are therefore optionally provided with an undoped intrinsic semiconductor region between a p-type semiconductor and an n-type semiconductor region. The intrinsic region may consist of single layer of material or a heterostructure consisting of multiple quantum wells and barriers

It is therefore preferred if the nanowires or nanopyramids are doped. Doping typically involves the introduction of impurity ions into the nanowire, e.g. during MBE or MOVPE growth. The doping level can be controlled from ˜10¹⁵/cm³ to 10²⁰/cm³. The nanowires or nanopyramids can be p-type doped or n-type doped as desired.

The n(p)-type semiconductors have a larger electron (hole) concentration than hole (electron) concentration by doping an intrinsic semiconductor with donor (acceptor) impurities. Suitable donor (acceptors) for III-V compounds can be Te, Sn (Be, Mg and Zn). Si can be amphoteric, either donor or acceptor depending on the site where Si goes to, depending on the orientation of the growing surface and the growth conditions. Dopants can be introduced during the growth process or by ion implantation of the nanowires or nanopyramids after their formation.

Higher carrier injection efficiency is required to obtain higher external quantum efficiency (EQE) of LEDs. However, the increasing ionization energy of Mg acceptors with increasing Al content in AlGaN alloys makes it difficult to obtain higher hole concentration in AlGaN alloys with higher Al content. To obtain higher hole injection efficiency (especially in the cladding/barrier layers consisting of high Al content), the inventors have devised a number of strategies which can be used individually or together.

There are problems to overcome in the doping process therefore. It is preferred if the nanowires or nanopyramids of the invention comprise Al. The use of Al is advantageous as high Al content leads to high band gaps, enabling UV-C LED emission from the active layer(s) of nanowires or nanopyramids and/or avoiding absorption of the emitted light in the doped cladding/barrier layers. Where the band gap is high, it is less likely that UV light is absorbed by this part of the nanowires or nanopyramids. The use therefore of AlN or AlGaN in nanowires or nanopyramids is preferred.

However, p-type doping of AlGaN or AlN to achieve high electrical conductivity (high hole concentration) is challenging as the ionization energy of Mg or Be acceptors increases with increasing Al content in AlGaN alloys. The present inventors propose various solutions to maximise electrical conductivity (i.e. maximise hole concentration) in AlGaN alloys with higher average Al content.

Where the nanowires or nanopyramids comprise AlN or AlGaN, achieving high electrical conductivity by introducing p-type dopants is a challenge. One solution relies on a short period superlattice (SPSL). In this method, we grow a superlattice structure consisting of alternating layers with different Al content instead of a homogeneous AlGaN layer with higher Al composition. For example, the cladding layer with 35% Al content could be replaced with a 1.8 to 2.0 nm thick SPSL consisting of, for example, alternating AlₓGa₁₋ₓN:Mg/Al_{y}Ga_{1-y}N:Mg with x=0.30/y=0.40. The low ionization energy of acceptors in layers with lower Al composition leads to improved hole injection efficiency without compromising on the barrier height in the cladding layer. This effect is additionally enhanced by the polarization fields at the interfaces. The SPSL can be followed with a highly p-doped GaN:Mg layer for better hole injection.

More generally, the inventors propose to introduce a p-type doped AlₓGa₁₋ₓN/Al_{y}Ga_{1-y}N short period superlattice (i.e. alternating thin layers of AlₓGa₁₋ₓN and Al_{y}Ga_{1-y}N) into the nanowires or nanopyramid structure, where the Al mole fraction x is less than y, instead of a p-type doped Al_{z}Ga_{1-z}N alloy where x<z<y. It is appreciated that x could be as low as 0 (i.e. GaN) and y could be as high as 1 (i.e. AlN). The superlattice period should preferably be 5 nm or less, such as 2 nm, in which case the superlattice will act as a single Al_{z}Ga_{1-z}N alloy (with z being a layer thickness weighted average of x and y) but with a higher electrical conductivity than that of the Al_{z}Ga_{1-z}N alloy, due to the higher p-type doping efficiency for the lower Al content AlₓGa₁₋ₓN layers.

In the nanowires or nanopyramids comprising a p-type doped superlattice, it is preferred if the p-type dopant is an alkali earth metal such as Mg or Be.

A further option to solve the problem of doping an Al containing nanowire/nanopyramid follows similar principles. Instead of a superlattice containing thin AlGaN layers with low or no Al content, a nanostructure can be designed containing a gradient of Al content (mole fraction) in the growth direction of the AlGaN within the nanowires or nanopyramids. Thus, as the nanowires or nanopyramids grow, the Al content is reduced/increased and then increased/reduced again to create an Al content gradient within the nanowires or nanopyramids.

This may be called polarization doping. In one method, the layers are graded either from GaN to AlN or AlN to GaN. The graded region from GaN to AlN and AlN to GaN may lead to n-type and p-type conduction, respectively. This can happen due to the presence of dipoles with different magnitude compared to its neighbouring dipoles. The GaN to AlN and AlN to GaN graded regions can be additionally doped with n-type dopant and p-type dopant respectively.

In a preferred embodiment, p-type doping is used in AlGaN nanowires using Be as a dopant.

Thus, one option would be to start with a GaN nanowire/nanopyramid and increase Al and decrease Ga content gradually to form AlN, perhaps over a growth thickness of 100 nm. This graded region could act as a p- or n-type region, depending on the crystal plane, polarity and whether the Al content is decreasing or increasing in the graded region, respectively. Then the opposite process is effected to produce GaN once more to create an n- or p-type region (opposite to that previously prepared). These graded regions could be additionally doped with n-type dopants such as Si and p-type dopants such as Mg or Be to obtain n- or p-type regions with high charge carrier density, respectively. The crystal planes and polarity is governed by the type of nanowire/nanopyramid as is known in the art.

Viewed from another aspect therefore, the nanowires or nanopyramids of the invention comprise Al, Ga and N atoms wherein during the growth of the nanowires or nanopyramids the concentration of Al is varied to create an Al concentration gradient within the nanowires or nanopyramids.

In a third embodiment, the problem of doping in an Al containing nanowire or nanopyramid is addressed using a tunnel junction. A tunnel junction is a barrier, such as a thin layer, between two electrically conducting materials. In the context of the present invention, the barrier functions as an ohmic electrical contact in the middle of a semiconductor device.

In one method, a thin electron blocking layer is inserted immediately after the active region, which is followed by a p-type doped AlGaN cladding layer with Al content higher than the Al content used in the active layers. The p-type doped cladding layer is followed by a highly p-type doped cladding layer and a very thin tunnel junction layer followed by an n-type doped AlGaN layer. The tunnel junction layer is chosen such that the electrons tunnel from the valence band in p-AlGaN to the conduction band in the n-AlGaN, creating holes that are injected into the p-AlGaN layer.

More generally, it is preferred if the nanowire or nanopyramid comprises two regions of doped GaN (one p- and one n-doped region) separated by an Al layer, such as a very thin Al layer. The Al layer might be a few nm thick such as 1 to 10 nm in thickness. It is appreciated that there are other optional materials that can serve as a tunnel junction which includes highly doped InGaN layers.

It is particularly surprising that doped GaN layers can be grown on the Al layer.

In one embodiment therefore, the invention provides a nanowire or nanopyramid having a p-type doped (Al)GaN region and an n-type doped (Al)GaN region separated by an Al layer.

The nanowires or nanopyramids of the invention can be grown to have a heterostructured form radially or axially. For example for an axial heterostructured nanowire or nanopyramid, p-n junction can be axially formed by growing a p-type doped core first, and then continue with an n-doped core (or vice versa). For a radially heterostructured nanowire or nanopyramid, p-n junction can be radially formed by growing the p-type doped nanowire or nanopyramid core first, and then the n-type doped semiconducting shell is grown (or vice versa)—a core shell nanowire. The core can also be axially heterostructured and the shell can be radially heterostructured. An intrinsic shell can be positioned between doped regions for a p-i-n nanowire. The NWs or nanopyramids are grown axially or radially and are therefore formed from a first section and a second section. The two sections are doped differently to generate a p-n junction or p-i-n junction. The first or second section of the NW or nanopyramid is the p-type doped or n-type doped section.

The nanowires or nanopyramids of the invention preferably grow epitaxially. They attach to the underlying substrate/intermediate layer through covalent, ionic or quasi van der Waals binding. Accordingly, at the junction of the substrate/intermediate layer and the base of the nanowire, crystal planes are formed epitaxially within the nanowire. These build up, one upon another, in the same crystallographic direction thus allowing the epitaxial growth of the nanowire. Preferably the nanowires or nanopyramids grow vertically. The term vertically here is used to imply that the nanowires or nanopyramids grow perpendicular to the support. It will be appreciated that in experimental science the growth angle may not be exactly 90° but the term vertically implies that the nanowires or nanopyramids are within about 10° of vertical/perpendicular, e.g. within 5°. Because of the epitaxial growth via covalent, ionic or quasi van der Waals bonding, it is expected that there will be an intimate contact between the nanowires or nanopyramids and the substrate/intermediate layer.

It will be appreciated that the substrate comprises a plurality of nanowires or nanopyramids. Preferably the nanowires or nanopyramids grow about parallel to each other. It is preferred therefore if at least 90%, e.g. at least 95%, preferably substantially all nanowires or nanopyramids grow in the same direction from the same plane of the substrate/intermediate layer.

It will be appreciated that there are many planes within a substrate from which epitaxial growth could occur. It is preferred if substantially all nanowires or nanopyramids grow from the same plane. It is preferred if that plane is parallel to the substrate/intermediate layer surface. Ideally the grown nanowires or nanopyramids are substantially parallel. Preferably, the nanowires or nanopyramids grow substantially perpendicular to the substrate/intermediate layer.

The nanowires of the invention should preferably grow in the [111] direction for nanowires or nanopyramids with cubic crystal structure and [0001] direction for nanowires or nanopyramids with hexagonal crystal structure. If the crystal structure of the growing nanowire or nanopyramid is cubic, then the (111) interface between the nanowire or nanopyramid and the substrate/intermediate layer represents the plane from which axial growth takes place. If the nanowire or nanopyramid has a hexagonal crystal structure, then the (0001) interface between the nanowire or nanopyramid and the substrate/intermediate layer represents the plane from which axial growth takes place. Planes (111) and (0001) both represent the same (hexagonal) plane of the nanowire, it is just that the nomenclature of the plane varies depending on the crystal structure of the growing nanowire.

The nanowires or nanopyramids are preferably grown by MBE or MOVPE. In the MBE method, the substrate/intermediate layer is provided with a molecular beam of each reactant, e.g. a group III element and a group V element preferably supplied simultaneously. A higher degree of control of the nucleation and growth of the nanowires or nanopyramids on the substrate/intermediate layer might be achieved with the MBE technique by using migration-enhanced epitaxy (MEE) or atomic-layer MBE (ALMBE) where e.g. the group III and V elements can be supplied alternatively.

A preferred technique is solid-source MBE, in which very pure elements such as gallium and arsenic are heated in separate effusion cells, until they begin to slowly evaporate (e.g. gallium) or sublimate (e.g. arsenic). The gaseous elements then condense on the substrate/intermediate layer, where they may react with each other. In the example of gallium and arsenic, single-crystal GaAs is formed. The use of the term “beam” implies that evaporated atoms (e.g. gallium) or molecules (e.g. As₄ or As₂) do not interact with each other or vacuum chamber gases until they reach the substrate/intermediate layer.

MBE takes place in ultra-high vacuum, with a background pressure of typically around 10⁻¹⁰ to 10⁻⁹ Torr. Nanostructures are typically grown slowly, such as at a speed of up to a few, such as about 10 μm per hour. This allows nanowires or nanopyramids to grow epitaxially and maximises structural performance.

In the MOVPE method, the substrate (and optionally intermediate layer) is/are kept in a reactor in which the substrate is provided with a carrier gas and a metal organic gas of each reactant, e.g. a metal organic precursor containing a group III element and a metal organic precursor containing a group V element preferably supplied simultaneously. The typical carrier gases are hydrogen, nitrogen or a mixture of the two. A higher degree of control of the nucleation and growth of the nanowires or nanopyramids on the substrate/intermediate layer might be achieved with the MOVPE technique by using pulsed layer growth technique, where e.g. the group III and V elements can be supplied alternatively.

### Selective Area Growth of Nanowires or Nanopyramids

The nanowires or nanopyramids of the invention may be grown by selective area growth (SAG) method, e.g. in the case of III-nitride nanowire. Inside the growth chamber in case of MBE or inside the reactor in case of MOVPE, the substrate temperature can be set to a temperature suitable for the growth of the nanowire or nanopyramid in question. In case of MBE, the growth temperature may be in the range 300 to 1000° C. The temperature employed is, however, specific to the nature of the material in the nanowire. For GaN, a preferred temperature is 700 to 950° C., e.g. 800 to 900° C., such as 810° C. For AlGaN the range is slightly higher, for example 800 to 980° C., such as 830 to 950° C., e.g. 850° C.

It will be appreciated therefore that the nanowires or nanopyramids can comprise different group III-V semiconductors within the nanowire, e.g. starting with a GaN stem followed by an AlGaN component or AlGaInN component and so on.

Nanowire growth can be initiated by opening the shutter of the Ga effusion cell, the nitrogen plasma cell, and the dopant cell simultaneously initiating the growth of doped GaN nanowires or nanopyramids, hereby called as stem. The length of the GaN stem can be kept between 10 nm to several 100s of nanometers. Subsequently, one could increase the substrate temperature if needed, and open the Al shutter to initiate the growth of AlGaN nanowires or nanopyramids. One could initiate the growth of AlGaN nanowires or nanopyramids on the substrate without the growth of GaN stem. n- and p-doped nanowires or nanopyramids can be obtained by opening the shutter of the n-dopant cell and p-dopant cell, respectively, during the nanowire or nanopyramid growth. For ex: Si dopant cell for n-doping of nanowires or nanopyramids, and Mg dopant cell for p-doping of nanowires or nanopyramids.

The temperature of the effusion cells can be used to control growth rate. Convenient growth rates, as measured during conventional planar (layer by layer) growth, are 0.05 to 2 μm per hour, e.g. 0.1 μm per hour. The ratio of Al/Ga can be varied by changing the temperature of the effusion cells.

The pressure of the molecular beams can also be adjusted depending on the nature of the nanowire or nanopyramid being grown. Suitable levels for beam equivalent pressures are between 1×10⁻⁷ and 1×10⁻⁴ Torr.

The beam flux ratio between reactants (e.g. group III atoms and group V molecules) can be varied, the preferred flux ratio being dependent on other growth parameters and on the nature of the nanowire or nanopyramid being grown. In the case of nitrides, nanowires or nanopyramids are always grown under nitrogen rich conditions.

It is an embodiment of the invention to employ a multistep, such as two step, growth procedure, e.g. to separately optimize the nanowire or nanopyramid nucleation and nanowire or nanopyramid growth.

In case of MOVPE, a significant benefit is that the nanowires or nanopyramids can be grown at a much faster growth rate. This method favours the growth of radial heterostructure nanowires or nanopyramids and microwires, for example: n-doped GaN core with shell consisting of intrinsic AlN/Al(In)GaN multiple quantum wells (MQW), AlGaN electron blocking layer (EBL), and p-doped (Al)GaN shell. This method also allows the growth of axial heterostructured nanowire or nanopyramid using techniques such as pulsed growth technique or continuous growth mode with modified growth parameters for e.g., lower V/III molar ratio and higher substrate temperature.

In more detail, the reactor must be evacuated after placing the sample, and is purged with N₂ to remove oxygen and water in the reactor. This is to avoid any damage to the graphene at the growth temperatures, and to avoid unwanted reactions of oxygen and water with the precursors. The total pressure is set to be between 50 and 400 Torr. After purging the reactor with N₂, the substrate is thermally cleaned under H₂ atmosphere at a substrate temperature of about 1200° C. The substrate temperature can then be set to a temperature suitable for the growth of the nanowire or nanopyramid in question. The growth temperature may be in the range 700 to 1200° C. The temperature employed is, however, specific to the nature of the material in the nanowire. For GaN, a preferred temperature is 800 to 1150° C., e.g. 900 to 1100° C., such as 1100° C. or 1000° C. For AlGaN the range is slightly higher, for example 900 to 1250° C., such as 1050 to 1250° C., e.g. 1250° C. or 1150° C.

The metal organic precursors for the nanowire or nanopyramid growth can be either trimethylgallium (TMGa), or triethylgallium (TEGa) for Ga, trimethylalumnium (TMAl) or triethylalumnium (TEAl) for Al, and trimethylindium (TMIn) or triethylindium (TEIn) for In. The precursors for dopants can be SiH₄ for silicon and bis(cyclopentadienyl)magnesium (Cp₂Mg) or bis(methylcyclopentadienyl)magnesium ((MeCp)₂Mg) for Mg. The flow rate of TMGa, TMAl and TMIn can be maintained between 5 and 100 sccm. The NH₃ flow rate can be varied between 5 and 150 sccm.

In particular, the simple use of vapour-solid growth may enable nanowire or nanopyramid growth. Thus, in the context of MBE, simple application of the reactants, e.g. In and N, to the substrate without any catalyst can result in the formation of a nanowire. This forms a further aspect of the invention which therefore provides the direct growth of a semiconductor nanowire or nanopyramid formed from the elements described above on a substrate. The term direct implies therefore the absence of a film of catalyst to enable growth.

### Catalyst-Assisted Growth of Nanowires or Nanopyramids

The nanowires or nanopyramids of the invention may also be grown in the presence of a catalyst. A catalyst can be introduced into those holes to provide nucleating sites for nanowire or nanopyramid growth. The catalyst can be one of the elements making up the nanowire or nanopyramid so-called self-catalysed, or different from any of the elements making up the nanowire.

For catalyst-assisted growth the catalyst may be Au or Ag or the catalyst may be a metal from the group used in the nanowire or nanopyramid growth (e.g. group III metal), especially one of the metal elements making up the actual nanowire or nanopyramid (self-catalysis). It is thus possible to use another element from group III as a catalyst for growing a III-V nanowire or nanopyramid e.g. use Ga as a catalyst for a Ga-group V nanowire or nanopyramid and so on. Preferably the catalyst is Au or the growth is self-catalysed (i.e. Ga for a Ga-group V nanowire or nanopyramid and so on). The catalyst can be deposited onto the substrate or intermediate layer in the holes patterned through the graphene and optionally masking layer to act as a nucleation site for the growth of the nanowires or nanopyramids. Ideally, this can be achieved by providing a thin film of catalytic material formed over the masking layer after holes have been etched in the layers. When the catalyst film is melted as the temperature increases to the NW or nanopyramid growth temperature, the catalyst forms nanometre sized particle-like droplets on the substrate or intermediate layer and these droplets form the points where nanowires or nanopyramids can grow.

This is called vapour-liquid-solid growth (VLS) as the catalyst is the liquid, the molecular beam is the vapour and the nanowire or nanopyramid provides the solid component. In some cases the catalyst particle can also be solid during the nanowire or nanopyramid growth, by a so called vapour-solid-solid growth (VSS) mechanism. As the nanowire or nanopyramid grows (by the VLS method), the liquid (e.g. gold) droplet stays on the top of the nanowire. It remains at the top of the nanowire or nanopyramid after growth and may therefore play a major role in contacting a top electrode.

As noted above, it is also possible to prepare self-catalysed nanowires or nanopyramids. By self-catalysed is meant that one of the components of the nanowire or nanopyramid acts as a catalyst for its growth.

For example, a Ga layer can be applied to the masking layer, melted to form droplets acting as nucleation sites for the growth of Ga containing nanowires or nanopyramids. Again, a Ga metal portion may end up positioned on the top of the nanowire.

In more detail and in the case of MBE-grown NWs, a Ga/In flux can be supplied to the substrate/intermediate layer surface for a period of time to initiate the formation of Ga/In droplets on the surface upon heating of the substrate. The substrate temperature can then be set to a temperature suitable for the growth of the nanowire or nanopyramid in question. The growth temperature may be in the range 300 to 700° C. The temperature employed is, however, specific to the nature of the material in the nanowire, the catalyst material and the substrate/intermediate layer material. For GaAs, a preferred temperature is 540 to 630° C., e.g. 590 to 630° C., such as 610° C. For InAs the range is lower, for example 420 to 540° C., such as 430 to 540° C., e.g. 450° C.

Nanowire growth can be initiated by opening the shutter of the Ga/In effusion cell and the counter ion effusion cell, simultaneously once a catalyst film has been deposited and melted.

The temperature of the effusion cells can be used to control growth rate. Convenient growth rates, as measured during conventional planar (layer by layer) growth, are 0.05 to 2 μm per hour, e.g. 0.1 μm per hour.

The pressure of the molecular beams can also be adjusted depending on the nature of the nanowire or nanopyramid being grown. Suitable levels for beam equivalent pressures are between 1×10⁻⁷ and 1×10⁻⁵ Torr.

The beam flux ratio between reactants (e.g. group III atoms and group V molecules) can be varied, the preferred flux ratio being dependent on other growth parameters and on the nature of the nanowire or nanopyramid being grown.

It has been found that the beam flux ratio between reactants can affect crystal structure of the nanowire. For example, using Au as a catalyst, growth of GaAs nanowires or nanopyramids with a growth temperature of 540° C., a Ga flux equivalent to a planar (layer by layer) growth rate of 0.6 μm per hour, and a beam equivalent pressure (BEP) of 9×10⁻⁶ Torr for As₄ produces wurtzite crystal structure. As opposed to this, growth of GaAs nanowires or nanopyramids at the same growth temperature, but with a Ga flux equivalent to a planar growth rate of 0.9 μm per hour and a BEP of 4×10⁻⁶ Torr for As₄, produces zinc blende crystal structure.

Nanowire diameter can in some cases be varied by changing the growth parameters. For example, when growing self-catalyzed GaAs nanowires or nanopyramids under conditions where the axial nanowire or nanopyramid growth rate is determined by the As₄ flux, the nanowire or nanopyramid diameter can be increased/decreased by increasing/decreasing the Ga:As₄ flux ratio. The skilled man is therefore able to manipulate the nanowire or nanopyramid in a number of ways. Moreover, the diameter could also be varied by growing a shell around the nanowire or nanopyramid core, making a core-shell geometry.

It is thus an embodiment of the invention to employ a multistep, such as two step, growth procedure, e.g. to separately optimize the nanowire or nanopyramid nucleation and nanowire or nanopyramid growth.

Moreover, the size of the holes can be controlled to ensure that only one nanowire or nanopyramid can grow in each hole. It is therefore preferred if only one nanowire or nanopyramid grows per hole in the mask. Finally, the holes can be made of a size where the droplet of catalyst that forms within the hole is sufficiently large to allow nanowire or nanopyramid growth. In this way, a regular array of nanowires or nanopyramids can be grown, even using Au catalysis.

It may be that as numerous nanowires grow from the substrate/intermediate layer that the nanowires coalesce at a certain distance from the substrate. The coalescence of nanowires may appear almost film like, as is discussed above

### Top Contact

In order to create an optoelectronic device, the top of the nanowires or nanopyramids needs to comprise a top contact. In one embodiment, a conventional top contact metal layer stack can be used.

In one embodiment, e.g. if the light reflective layer is not conductive, a top contact is formed using another graphene layer. The invention then involves placing a graphene layer on top of the formed nanowires or nanopyramids to make a top contact. It is preferred that the graphene top contact layer is substantially parallel with the lower graphene layer. It will also be appreciated that the area of the graphene layer does not need to be the same as the area of the lower graphene layer. It may be that a number of graphene layers are required to form a top contact with a substrate with an array of nanowires or nanopyramids.

The graphene layers used can be the same as those described in detail above in connection with the graphene electrical contact layer.

It is preferred if the top contact is 20 nm in thickness or less. Even more preferably, the graphene top contact may be 5 nm or less in thickness.

When graphene contacts directly to the semiconductor nanowires or nanopyramids, it usually forms a Schottky contact which hinders the electrical current flow by creating a barrier at the contact junction. Due to this problem, the research on graphene deposited on semiconductors has been mainly confined to the use of graphene/semiconductor Schottky junctions.

Application of the top contact to the formed nanowires or nanopyramids can be achieved by any convenient method. Methods akin to those mentioned previously for transferring graphitic layers to substrates may be used. The graphitic layers from Kish graphite, highly ordered pyrolytic graphite (HOPG), or CVD may be exfoliated by mechanical or chemical methods. Then they can be transferred into etching solutions such as HF or acid solutions to remove Cu (Ni, Pt, etc.) (especially for CVD grown graphitic layers) and any contaminants from the exfoliation process. The etching solution can be further exchanged into other solutions such as deionised water to clean the graphitic layers. The graphene layers can then be easily transferred onto the formed nanowires or nanopyramids as the top contact. Again e-beam resist or photoresist may be used to support the thin graphene layers during the exfoliation and transfer processes, which can be removed easily after deposition.

It is preferred if the graphene layers are dried completely after etching and rinsing, before they are transferred to the top of the nanowire or nanopyramid arrays. To enhance the contact between graphene layers and nanowires or nanopyramids a mild pressure and heat can be applied during this “dry” transfer.

Alternatively, the graphene layers can be transferred on top of the nanowire or nanopyramid arrays, together with a solution (e.g. deionised water). As the solution dries off, the graphene layers naturally form a close contact to underlying nanowires or nanopyramids. In this “wet” transfer method, the surface tension of the solution during the drying process might bend or knock out the nanowire or nanopyramid arrays. To prevent this, where this wet method is used, more robust nanowires or nanopyramids are preferably employed. Nanowires having a diameter of >80 nm might be suitable. One may also use the critical-point drying technique to avoid any damage caused by surface tension during the drying process. Another way to prevent this is to use supporting and electrically isolating material as fill-in material between nanowires or nanopyramids.

If there is a water droplet on a nanowire or nanopyramid array and attempts to remove it involve, for example a nitrogen blow, the water drop will become smaller by evaporation, but the drop will always try to keep a spherical form due to surface tension. This could damage or disrupt the nanostructures around or inside the water droplet.

Critical point drying circumvents this problem. By increasing temperature and pressure, the phase boundary between liquid and gas can be removed and the water can be removed easily.

Also doping of the graphene top contact can be utilized. The major carrier of the graphene top contact can be controlled as either holes or electrons by doping. It is preferable to have the same doping type in the graphene top contact and in the semiconducting nanowires or nanopyramids.

### Applications

Semiconductor nanowires or nanopyramids have wide ranging utility. They are semiconductors so can be expected to offer applications in any field where semiconductor technology is useful. They are primarily of use in integrated nanoelectronics and nano-optoelectronic applications.

An ideal device for their deployment might be a solar cell, LED or photodetector. One possible device is a nanowire or nanopyramid solar cell sandwiched between two graphene layers as the two terminals.

Such a solar cell has the potential to be efficient, cheap and flexible at the same time. This is a rapidly developing field and further applications on these valuable materials will be found in the next years. The same concept can be used to also fabricate other opto-electronic devices such as light-emitting diodes (LEDs), waveguides and lasers.

Preferably, the semiconductor nanowires or nanopyramids have utility in LEDs, in particular UV LEDs and especially UV-A, UV-B, or UV-C LEDs. The LEDs are preferred designed as a so called “flip chip” where the chip is inverted compared to a normal device.

The whole LED arrangement can be provided with contact pads for flip-chip bonding distributed and separated to reduce the average series resistance. Such a nanostructured LED can be placed on a carrier having contact pads corresponding to the position of p-contact pads and n-contact pads on the nanowire or nanopyramid LED chip and attached using soldering, ultrasonic welding, bonding or by the use of electrically conductive glue. The contact pads on the carrier can be electrically connected to the appropriate power supply lead of the LED package.

Nanowire-based LED devices as such, are usually mounted on a carrier that provides mechanical support and electrical connections. One preferred way to construct a LED with improved efficiency is to make a flip-chip device. A light reflective layer with high reflectivity is formed on top of the nanowires or nanopyramids. The support is preferably sufficiently transparent to allow for light to be emitted through said substrate layer. Similar considerations apply to the intermediate layer, if present. In a particular embodiment, the intermediate layer is transparent. Emitted light directed towards the top of the nanowires or nanopyramids is reflected when it encounters the reflective layer, thus creating a clearly dominating direction for the light leaving the structure. This way of producing the structure allows for a much larger fraction of the emitted light to be guided in a desired direction, increasing the efficiency of the LED. The invention therefore enables the preparation of visible LEDs and UV LEDs.

The invention also relates to photodetectors in which the device absorbs light and generates a photocurrent. The light reflective layer may reflect light entering the device back on to the nanowires or nanopyramids for enhanced light detection.

Viewed from another aspect the invention provides a light emitting diode device comprising:

a graphene layer carried directly on a sapphire, Si, SiC or group III-V semiconductor substrate; and

an oxide or nitride masking layer directly on top of said graphene layer;

wherein a plurality of holes are present through said graphene layer and through said masking layer to said substrate;

a plurality of nanowires or nanopyramids are grown from said substrate in said holes, said nanowires or nanopyramids comprising at least one semiconducting group III-V compound;

a light reflective layer in electrical contact with the top of at least a portion of said nanowires or nanopyramids, said light reflective layer optionally acting as an electrode;

optionally an electrode in electrical contact with the top of at least a portion of said nanowires or nanopyramids, said second electrode being essential where said light reflective layer does not act as an electrode;

and wherein in use light is emitted from said device in a direction substantially opposite to said light reflective layer.

Viewed from another aspect the invention provides a photodetector device comprising:

a graphene layer carried directly on a sapphire, Si, SiC or group III-V semiconductor substrate; and

an oxide or nitride masking layer directly on top of said graphene layer;

wherein a plurality of holes are present through said graphene layer and through said masking layer to said substrate;

a plurality of nanowires or nanopyramids are grown from said substrate in said holes, said nanowires or nanopyramids comprising at least one semiconducting group III-V compound;

an electrode in contact with the top of at least a portion of said nanowires or nanopyramids optionally in the form of a light reflective layer;

and wherein in use light is absorbed in said device.

Viewed from another aspect the invention provides a light emitting diode device comprising:

a graphene layer carried directly on a sapphire, Si, SiC, Ga₂O₃, or group III-V semiconductor substrate, or directly on an intermediate group III-V semiconductor layer positioned directly on top of said substrate; and

optionally an oxide, nitride or fluoride masking layer directly on top of said graphene layer;

wherein a plurality of holes are present through said graphene layer and through said optional masking layer to said substrate/intermediate layer;

a plurality of nanowires or nanopyramids are grown from said substrate/intermediate layer in said holes, said nanowires or nanopyramids comprising at least one semiconducting group III-V compound;

a light reflective layer in electrical contact with the top of at least a portion of said nanowires or nanopyramids, said light reflective layer optionally acting as an electrode;

optionally an electrode in electrical contact with the top of at least a portion of said nanowires or nanopyramids, said second electrode being essential where said light reflective layer does not act as an electrode;

and wherein in use light is emitted from said device in a direction substantially opposite to said light reflective layer.

Viewed from another aspect the invention provides a photodetector device comprising:

a graphene layer carried directly on a sapphire, Si, SiC, Ga₂O₃, or group III-V semiconductor substrate, or directly on an intermediate group III-V semiconductor layer positioned directly on top of said substrate; and

optionally an oxide, nitride or fluoride masking layer directly on top of said graphene layer;

wherein a plurality of holes are present through said graphene layer and through said optional masking layer to said substrate/intermediate layer;

a plurality of nanowires or nanopyramids are grown from said substrate/intermediate layer in said holes, said nanowires or nanopyramids comprising at least one semiconducting group III-V compound;

an electrode in contact with the top of at least a portion of said nanowires or nanopyramids optionally in the form of a light reflective layer;

and wherein in use light is absorbed in said device.

It will be appreciated that devices of the invention are provided with electrodes to enable charge to be passed into the device.

The invention will now be further discussed in relation to the following non limiting examples and figures.

### BRIEF DESCRIPTION OF THE FIGURES

FIGS. 1-7 concern positioned nanowires/nanopyramids using graphene as a hole mask on a crystalline substrate/intermediate-layer and experimental results of LEDs fabricated using this method. FIGS. 8-16 concern positioned nanowires/nanopyramids using the deposition of a hole mask layer on graphene on a crystalline substrate/intermediate-layer and experimental results of a LED fabricated using this method.

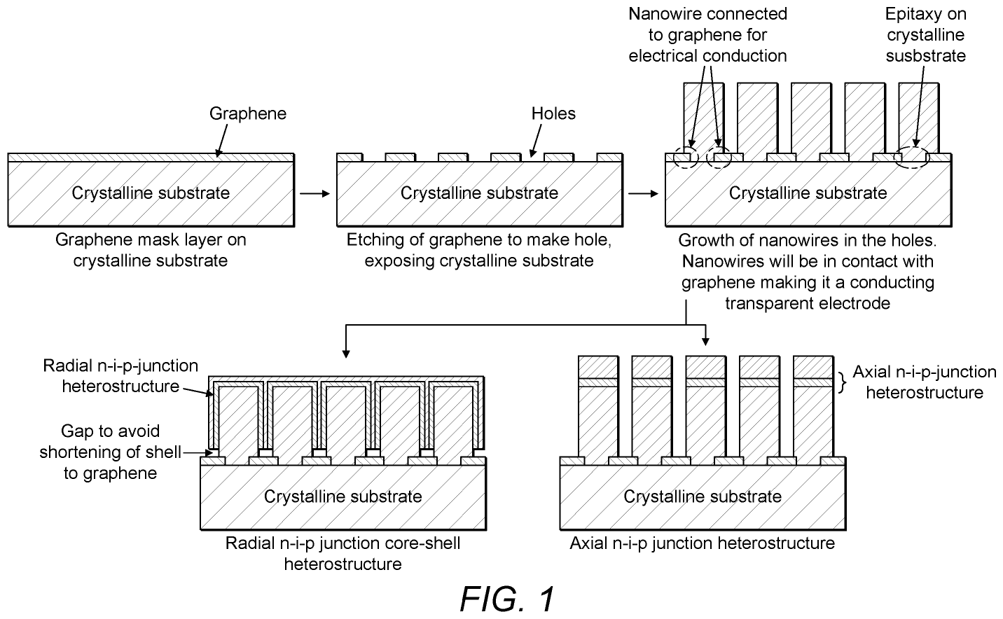

FIG. 1 (case 1.1) shows positioned flat-tip nanowires grown epitaxially on a crystalline substrate/intermediate-layer carrying a graphene mask layer through which holes have been etched. The nanowires first nucleate on the substrate/intermediate-layer epitaxially through the holes in the graphene. As the nanowires continue to grow both axially and radially, they also grow on top of the graphene layer maintaining the epitaxial relationship with the substrate/intermediate-layer. The graphene layer forms electrical contact with the nanowires both by nanowire contact with the graphene surface as well as contact with the edges of the graphene holes. Hence the graphene layer forms a conductive transparent electrode. The nanowires can be grown with either an axial or radial heterostructure in order to fabricate axial or radial n-i-p/p-i-n junction nanowire device structures, respectively. In the case of the radial n-i-p/p-i-n junction nanowire device structure, growth of the p/n nanowire shell layer on graphene must be avoided (gaps needed) to avoid shortening between n/p nanowire core and p/n nanowire shell.

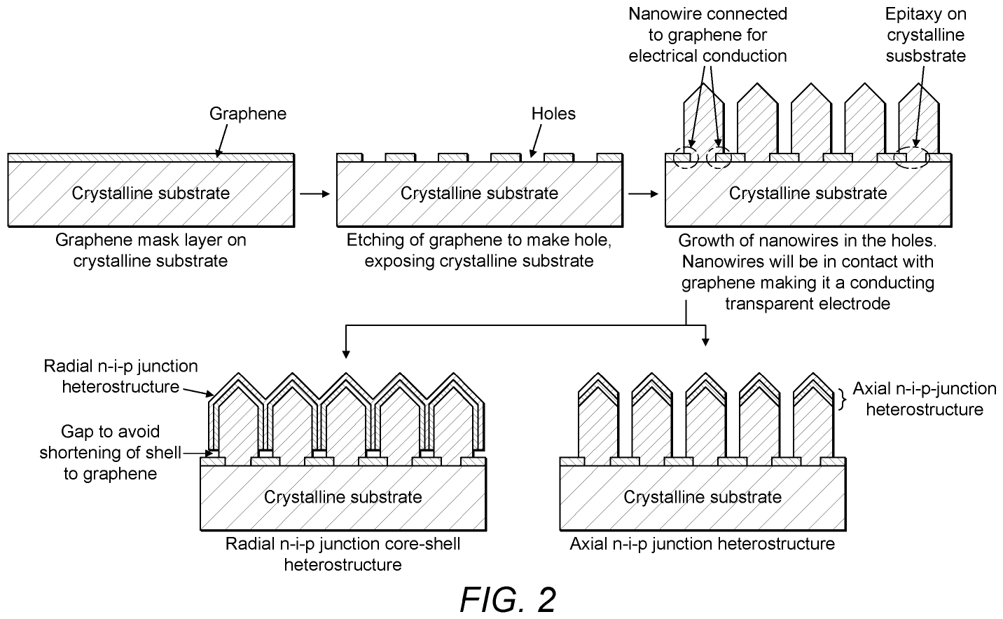

FIG. 2 (case 1.2) is analogous to FIG. 1, with the only difference being that the nanowires have a pyramidal tip. FIG. 2 shows positioned pyramid-tip nanowires grown epitaxially on a crystalline substrate/intermediate-layer carrying a graphene mask layer through which holes have been etched.

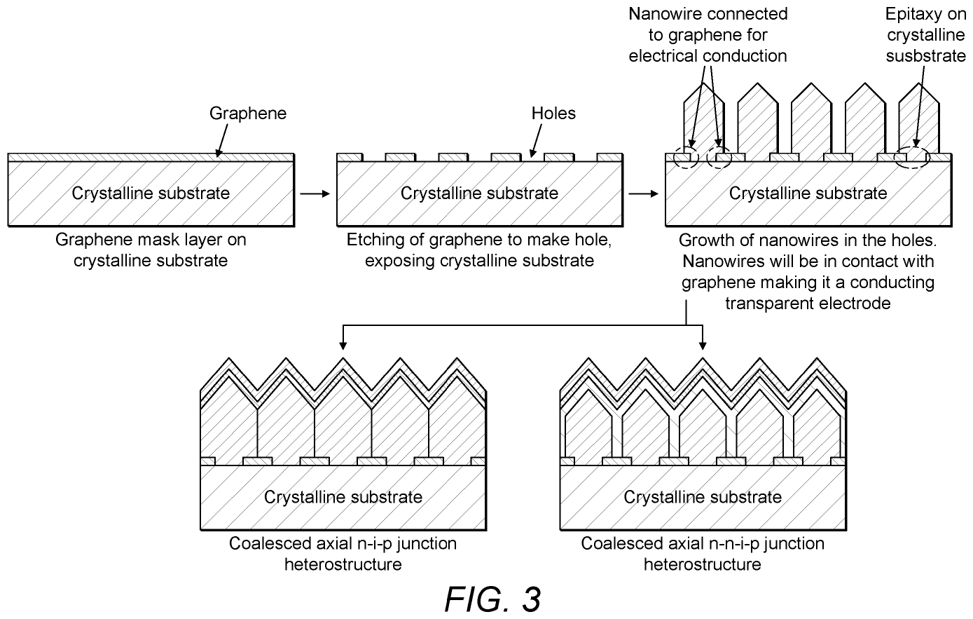

FIG. 3 (case 1.3) is analogous to the axial n-i-p junction device of FIG. 2, but the nanowires in FIG. 3 are completely coalesced as a result of the growth of an additional n-AlGaN nanowire shell layer. FIG. 3 therefore shows positioned pyramid-tip nanowires grown epitaxially on a crystalline substrate/intermediate-layer carrying a graphene mask layer through which holes have been etched, but the nanowires are completely coalesced as a result of the growth of an additional n-AlGaN nanowire shell layer.

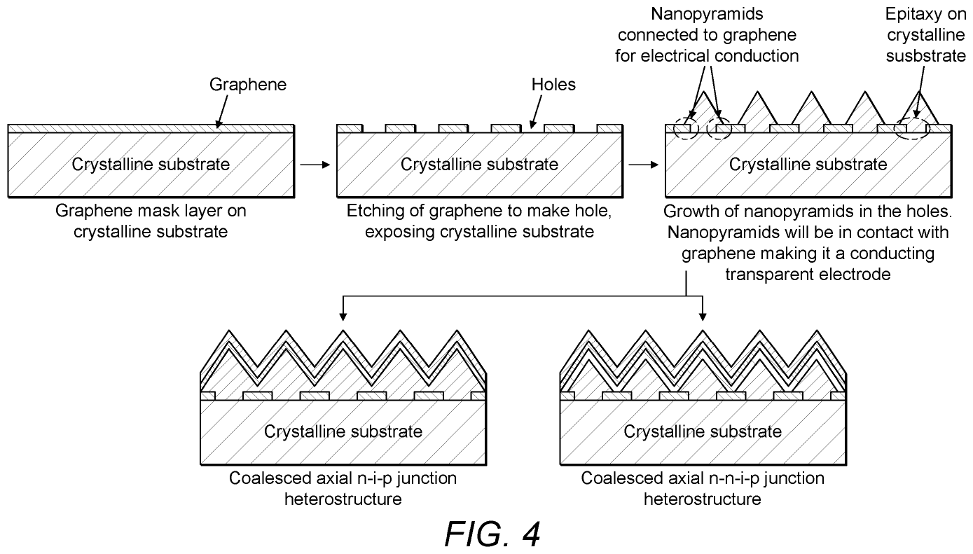

FIG. 4 (case 1.4) is analogous to FIG. 3, but with coalesced nanopyramids instead of coalesced nanowires. FIG. 4 therefore shows positioned nanopyramids grown epitaxially on a crystalline substrate/intermediate-layer carrying a graphene mask layer through which holes have been etched, and the nanopyramids are completely coalesced as a result of the growth of an additional n-AlGaN nanowire shell layer.

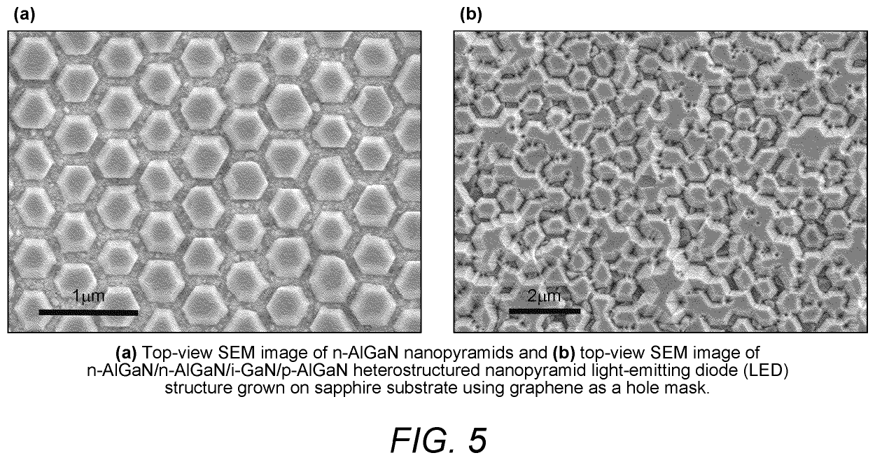

FIG. 5 depicts nanopyramid growth on a graphene hole mask layer on a sapphire (0001) substrate. The grown structure is a coalesced axial n-n-i-p junction GaN/AlGaN nanopyramid light emitting diode (LED) structure (as schematically described in FIG. 4 above). FIG. 5a is a top-view SEM image taken after the initial growth of n-AlGaN nanopyramids and FIG. 5b is a top-view SEM image taken after the complete growth of the n-AlGaN/n-AlGaN/i-GaN/p-AlGaN nanopyramid LED structure.

FIG. 6 demonstrates device characteristics of the sample shown in FIG. 5b processed into a flip-chip LED with a size of 50 μm×50 μm. (a) Current-voltage curve and (b) electroluminescence (EL) spectrum of the corresponding LED showing emission at 360 nm.

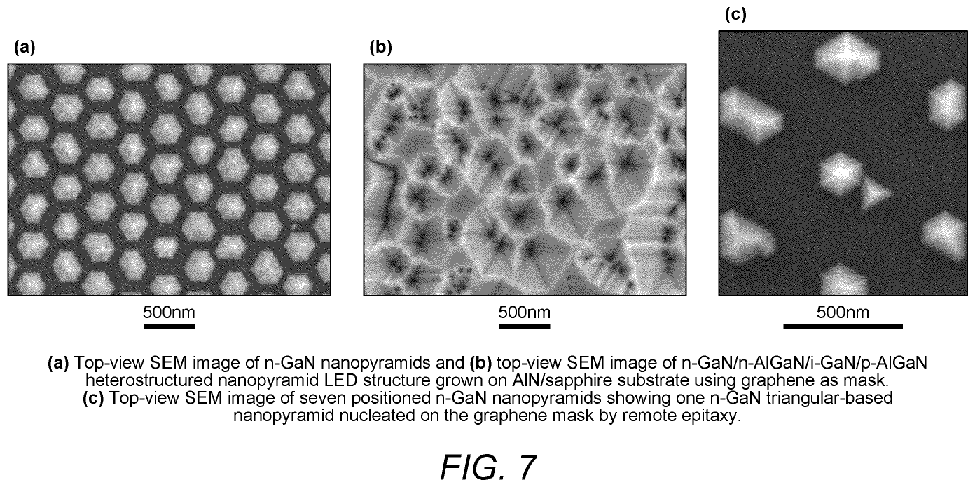

FIG. 7 depicts nanopyramid growth on a graphene hole mask layer on an AlN/sapphire (0001) substrate. The grown coalesced structure is an axial n-n-i-p junction GaN/AlGaN nanopyramid light emitting diode (LED) structure (as schematically described in FIG. 4 above). FIG. 7a is a top-view SEM image taken after the initial growth of n-GaN nanopyramids and FIG. 7b is a top-view SEM image taken after the complete growth of the n-GaN/n-AlGaN/i-GaN/p-AlGaN nanopyramid LED structure. FIG. 7c shows a top-view SEM image of seven positioned n-GaN nanopyramids showing one n-GaN triangular-based nanopyramid nucleated on the graphene mask by remote epitaxy. One can see that the nanoisland has nucleated with its three facets parallel to the facet orientation of three of the six facets of the hexagonal nanopyramid. FIG. 7d demonstrates the current-voltage curve of the sample shown in FIG. 7b processed into a flip-chip LED with a size of 50 μm×50 μm.

FIG. 8 (case 2.1) shows positioned flat-tip nanowires grown epitaxially on a crystalline substrate/intermediate-layer carrying a mask layer on top of graphene through which holes are etched through both masking layer and graphene layer to expose the crystalline substrate/intermediate layer below. The nanowires first nucleate epitaxially on the crystalline substrate/intermediate-layer exposed through the holes in the mask layer. As the nanowires continue to grow both axially and radially, they also grow on top of the mask layer maintaining the epitaxial relationship with the substrate/intermediate-layer. The graphene layer forms electrical contact with the nanowires by nanowire contact with the edges of the graphene holes. Hence the graphene layer forms a conductive transparent electrode. The nanowires can be grown with either an axial or radial heterostructure in order to fabricate axial or radial n-i-p/p-i-n junction nanowire device structures, respectively.

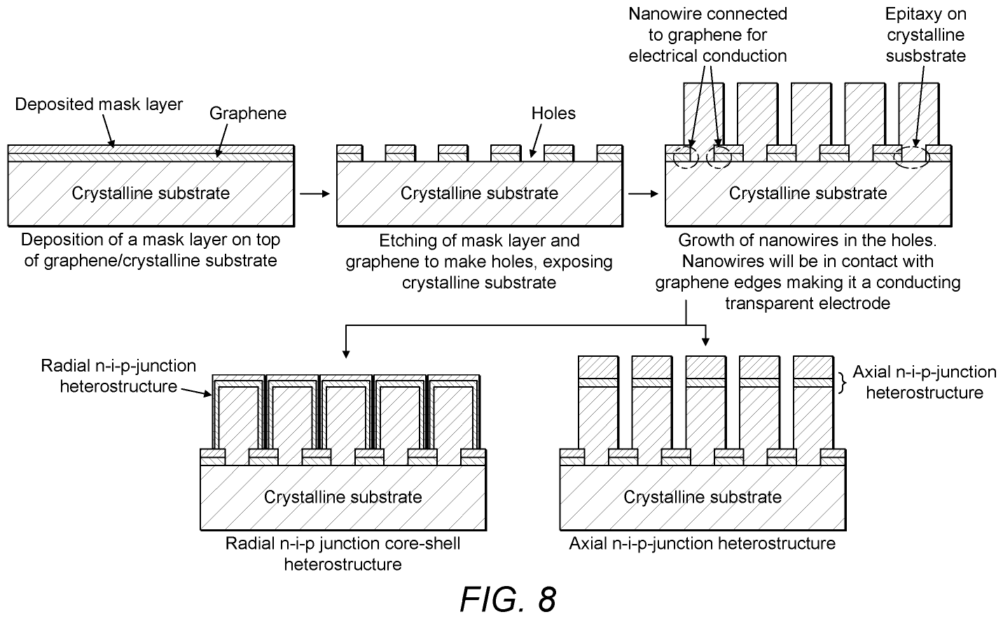

FIG. 9 (case 2.2) is analogous to FIG. 8, with the only difference being that the nanowires have a pyramidal tip. FIG. 9 therefore shows positioned pyramid-tip nanowires grown epitaxially on a crystalline substrate/intermediate-layer carrying a mask layer on top of graphene through which holes are etched through both masking layer and graphene layer to expose the crystalline substrate/intermediate layer below.

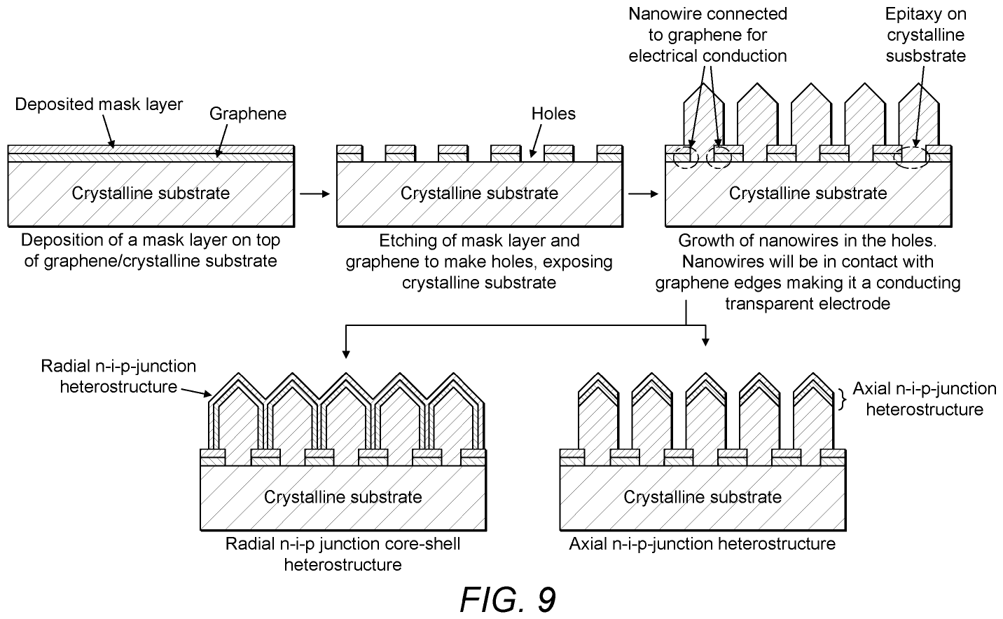

FIG. 10 (case 2.3) is analogous to the axial n-i-p junction heterostructure of FIG. 9, but the nanowires in FIG. 10 are completely coalesced as a result of the growth of an additional n-AlGaN nanowire shell layer. FIG. 10 therefore shows positioned pyramid-tip nanowires grown epitaxially on a crystalline substrate/intermediate-layer carrying a mask layer on top of graphene through which holes are etched through both masking layer and graphene layer to expose the crystalline substrate/intermediate layer below, but the nanowires are completely coalesced as a result of the growth of an additional n-AlGaN nanowire shell layer

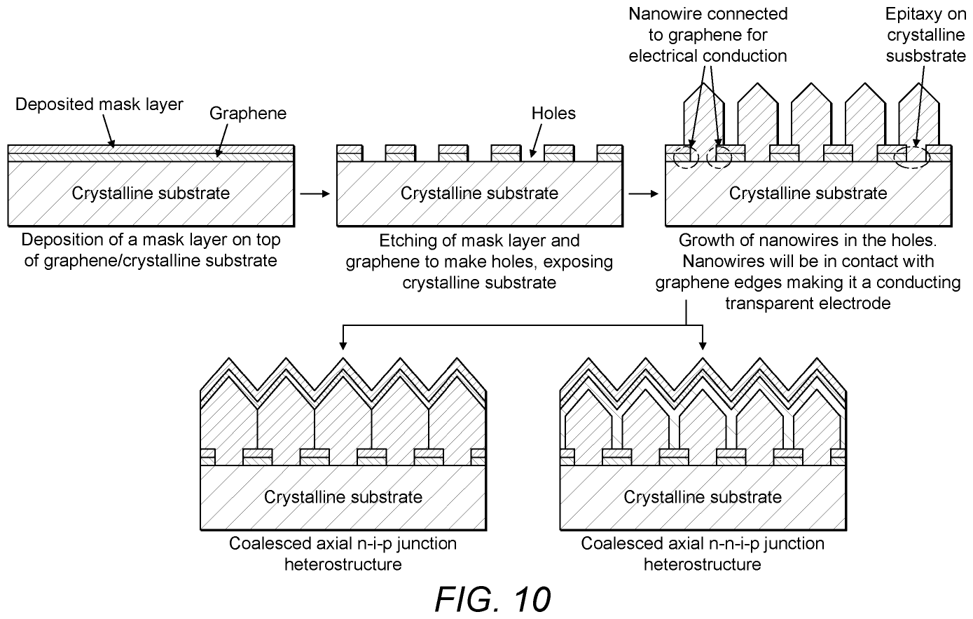

FIG. 11 (case 2.4) is analogous to FIG. 10, but with coalesced nanopyramids instead of coalesced nanowires. FIG. 11 therefore shows positioned nanopyramids grown epitaxially on a crystalline substrate/intermediate-layer carrying a mask layer on top of graphene through which holes are etched through both masking layer and graphene layer to expose the crystalline substrate/intermediate layer below, but the nanopyramids are completely coalesced as a result of the growth of an additional n-AlGaN nanowire shell layer.

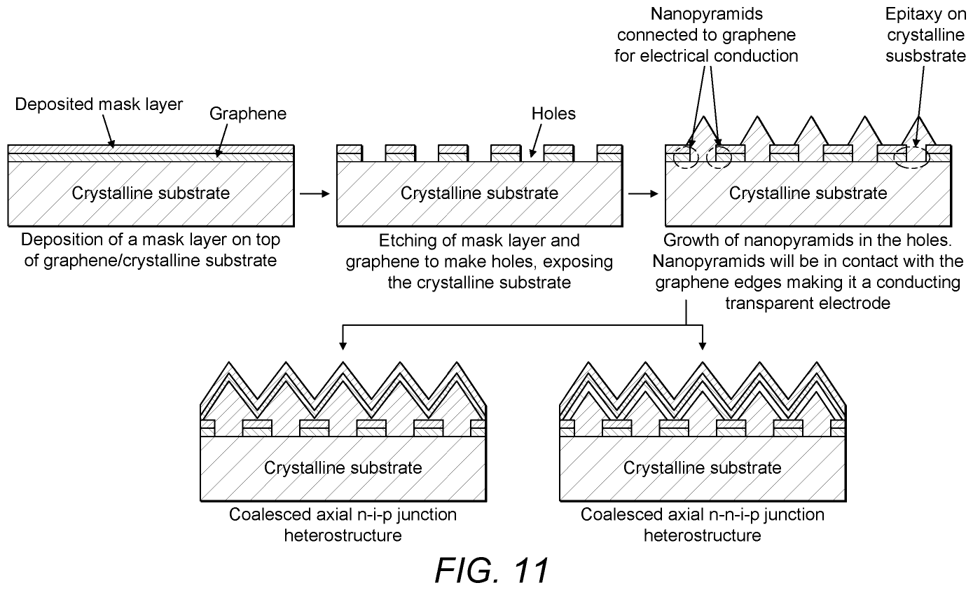

FIG. 12 depicts nanowire growth using a silicon oxide hole mask layer deposited on graphene carried on a sapphire (0001) substrate. The grown coalesced structure is an axial n-n-i-p junction GaN/AlGaN nanowire light emitting diode (LED) structure (as schematically described in FIG. 10 above). FIG. 12a is a bird-view SEM image taken after the initial growth of n-AlGaN nanowires and FIG. 12b is a bird-view SEM image taken after the complete growth of the n-AlGaN/n-AlGaN/i-GaN/p-AlGaN nanowire LED structure.

FIG. 13 demonstrates device characteristics of the sample shown in FIG. 12b processed into a flip-chip LED with a size of 50 μm×50 μm. (a) Current-voltage curve and (b) electroluminescence (EL) spectrum of the corresponding LED showing emission at 372 nm.

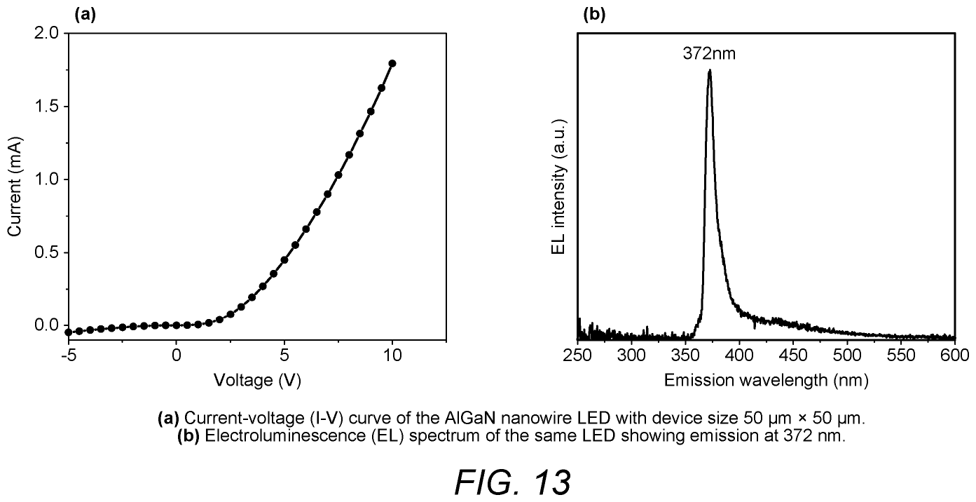

FIG. 14 (case 2.2) contrasts AlGaN nanowire growth directly on sapphire (0001) substrate using silicon oxide layer and graphene as combined hole mask with growth directly on graphene using a silicon oxide layer as hole mask. FIGS. 14a and b demonstrate the growth that occurs in the present invention. Here the AlGaN nanowires are directly grown on sapphire substrate. The nanowires have uniform morphology and same in-plane orientation. Corners face each other (FIG. 14a) or facets face each other (FIG. 14b). In contrast, FIG. 14c shows the nanowire structure that occurs when growth is effected directly on graphene using a silicon oxide mask. The nanowires have a non-uniform morphology and random in-plane orientation.

FIG. 15 (case 3.1) shows an embodiment in which the holes etched in the silicon oxide masking layer are larger than those etched in the graphene layer. This exposes the graphene layer below to allow a better electrical contact to be made with the axial and/or radial heterostructured nanowires, especially in the context of radial nanowire core-shell type device structures.

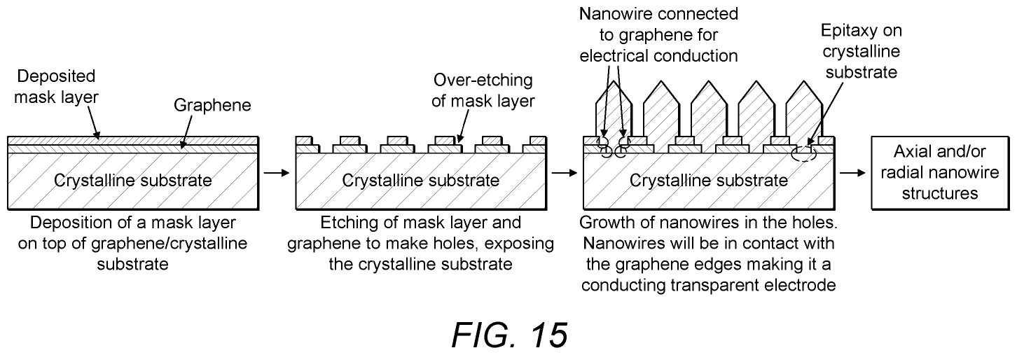

FIG. 16 (case 3.2) is analogous to FIG. 15, but with nanopyramids.

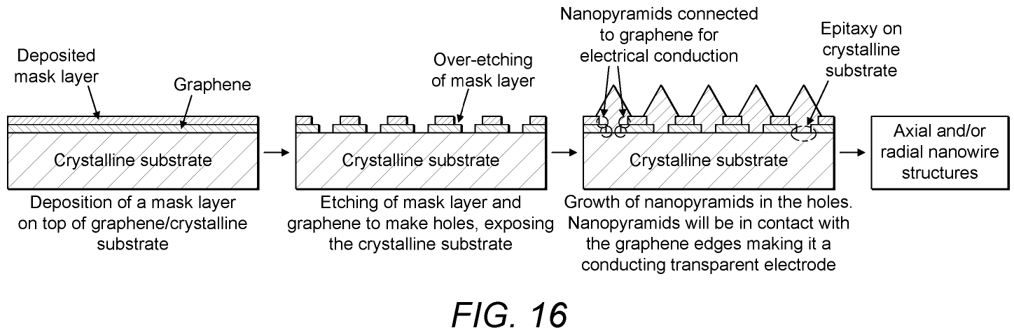

### EXAMPLES

### Experimental Procedure of Growing Positioned AlGaN NWs/NPs.

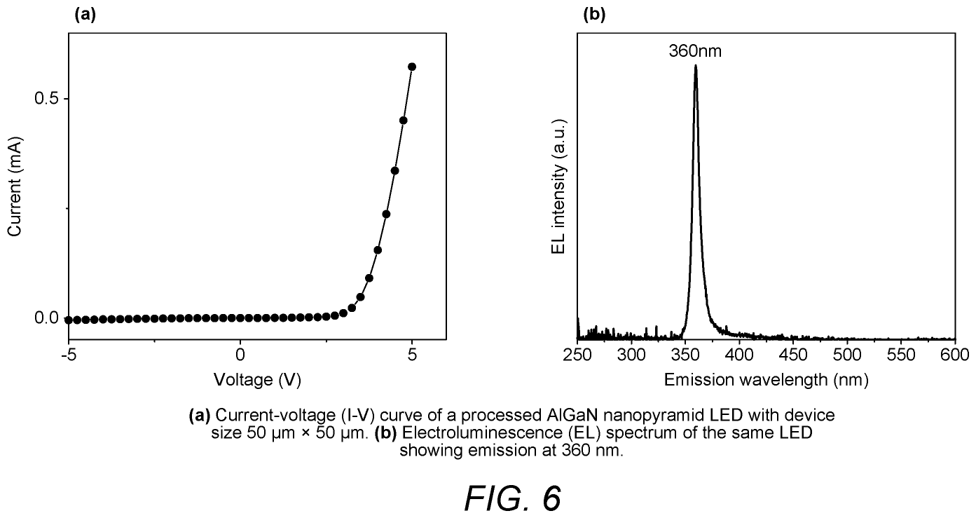

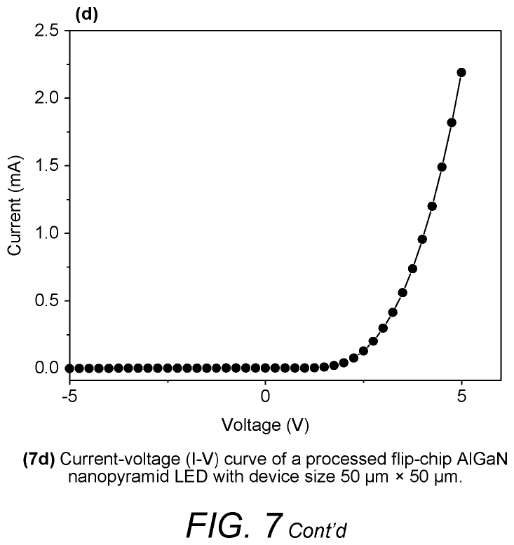

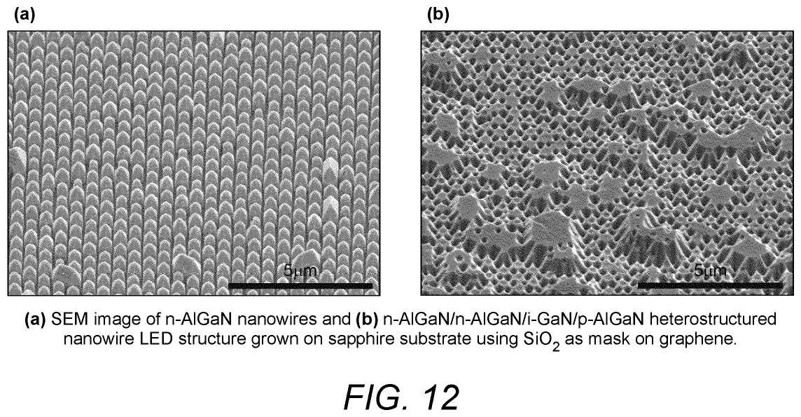

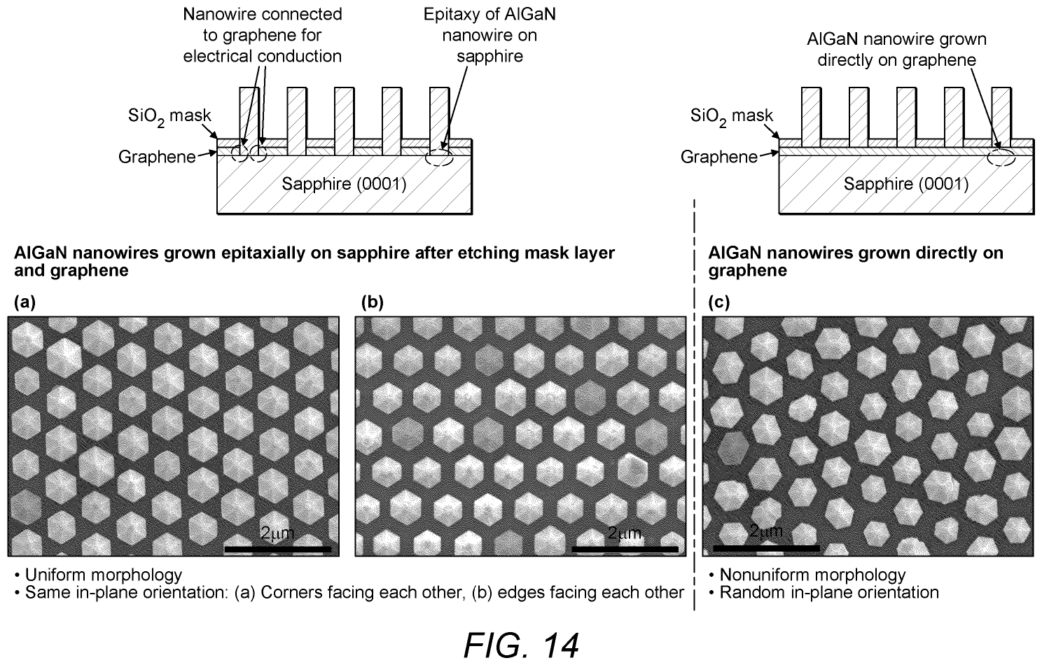

Graphene was grown by CVD on Cu foil and subsequently transferred onto sapphire (0001) substrates (for the growth shown in FIGS. 5, 12 and 14) or AlN/sapphire (0001) substrates (for the growth shown in FIG. 7) for the experiments. A silicon oxide (SiO₂) mask layer of thickness 30-50 nm was deposited on the graphene layer for the experiments shown in FIGS. 12 and 14. Electron-beam lithography was used for the hole patterning. The SiO₂ mask layer and the graphene layer was etched by a combination of wet and dry etching (for the experiments in FIGS. 12 and 14) whereas the graphene layer was etched by dry etching (for the experiments in FIGS. 5 and 7). This process exposes the sapphire substrate (for the growth shown in FIGS. 5, 12 and 14) or AlN-template surface (for the growth shown in FIG. 7) in the hole. The nanowire/nanopyramid growth was carried out in an MOCVD reactor. Trimethylaluminum (TMAl), trimethylgallium (TMGa), and ammonia (NH₃) were used as precursors for Al, Ga, and N, respectively. Silane was supplied during the growth of the n-AlGaN (for the growth shown in FIGS. 5a, 12a and 14) or n-GaN (for the growth shown in FIGS. 7a and 7c) NWs/NPs for n-type doping. For growing the full LED structures after growing the n-AlGaN/n-AlGaN (for the growth shown in FIGS. 5b and 12b) or n-GaN/n-AlGaN (for the growth shown in FIG. 7b) NWs/NPs, an intrinsic GaN active layer followed by p-AlGaN and p-GaN layers were grown. Bis-cyclopentadienyl magnesium (Cp₂Mg) was used as the precursor for Mg for the p-type doping. Mg dopants were activated by an annealing process under N₂ ambient.

### Comparison of NW Growth Directly on Graphene Vs on Sapphire.

FIG. 14(a) shows top-view SEM image of the same positioned AlGaN NWs as in FIG. 12(a). Here the corners of the hexagonal NWs are facing each other. FIG. 14(b) shows top-view SEM image of positioned AlGaN NW using the same growth condition as in FIG. 14(a) but the hole pattern was rotated by 30° with respect to the in-plane sapphire surface orientation during electron beam lithography. Here the edges of the hexagonal NWs are facing each other. In both cases (FIG. 14(a,b)), NWs are uniform and have the same in-plane orientation. To compare the NWs grown directly on sapphire with the NWs grown directly on graphene, one additional hole pattern sample was prepared. In this case, graphene was not etched in the holes, i.e. the sapphire substrate was not exposed in the holes. FIG. 14(c) shows top-view SEM image of AlGaN NWs grown directly on graphene using the same growth condition as in FIG. 14(a,b). It can be seen that the NWs are non-uniform and have random in-plane orientation.

1. A composition of matter comprising:
a sapphire, Si, SiC, Ga₂O₃ or group III-V semiconductor substrate;
an intermediate group III-V semiconductor layer directly on top of said substrate;
a graphene layer directly on top of said intermediate layer;
wherein a plurality of holes are present through said graphene layer; and wherein
a plurality of nanowires or nanopyramids are grown from said intermediate layer in said holes, said nanowires or nanopyramids comprising at least one semiconducting group III-V compound.

2. A composition of matter comprising:
a graphene layer carried directly on a sapphire, Si, SiC, Ga₂O₃ or group III-V semiconductor substrate;
wherein a plurality of holes are present through said graphene layer; and wherein
a plurality of nanowires or nanopyramids are grown from said substrate in said holes, said nanowires or nanopyramids comprising at least one semiconducting group III-V compound.

3. A composition as claimed in any preceding claim, further comprising group III-V nanoislands grown directly on the graphene layer.

4. A composition as claimed in claim 3, wherein the epitaxy, crystal orientation and facet orientations of said nanoislands are directed by the intermediate layer, if present, or by the substrate if there is no intermediate layer.

5. A composition of matter as claimed in any of claim 1 or 3-4, wherein the intermediate layer is GaN, AlGaN, AlInGaN or AlN, preferably AlN.

6. A composition of matter as claimed in any of claim 1 or 3-5, wherein the intermediate layer has a thickness of less than 200, preferably less than 100 nm, more preferably less than 75 nm.

7. A composition of matter as claimed in any preceding claim, wherein the composition does not comprise an additional masking layer directly on top of said graphene layer, e.g. does not comprise an oxide, nitride or fluoride masking layer directly on top of said graphene layer.

8. A composition of matter as claimed in any preceding claim, wherein at least some or all of said nanowires or nanopyramids and optionally nanoislands are coalesced.

9. A composition as claimed in any preceding claim in which said nanowires or nanopyramids grow epitaxially from the substrate or intermediate layer through the holes in graphene.

10. A composition as claimed in any preceding claim in which said graphene layer is up to 20 nm in thickness, preferably up to 10 nm, more preferably up to 5 nm, more preferably up to 2 nm in thickness.

11. A composition as claimed in any preceding claim in which the substrate comprises sapphire, especially sapphire (0001).

12. A composition as claimed in any preceding claim in which said nanowires or nanopyramids are doped.

13. A composition as claimed in any preceding claim in which said nanowires or nanopyramids are axially heterostructured.

14. A composition as claimed in any preceding claim in which said nanowires or nanopyramids are core-shell or radially heterostructured.

15. A composition as claimed in any preceding claim wherein a graphitic top contact layer or conventional metal contact or metal stack contact layer is present on top of said nanowires or nanopyramids.

16. A composition as claimed in any preceding claim wherein the surface of the graphene layer is chemically/physically modified to modify its electrical properties.

17. A composition of matter comprising:
a graphene layer carried directly on a sapphire, Si, SiC, Ga₂O₃ or group III-V semiconductor substrate; and
an oxide, nitride or fluoride masking layer directly on top of said graphene layer;
wherein a plurality of holes are present through said graphene layer and through said masking layer to said substrate; and wherein
a plurality of nanowires or nanopyramids are grown from said substrate in said holes, said nanowires or nanopyramids comprising at least one semiconducting group III-V compound.

18. A composition as claimed in claim 17 in which said nanowires or nanopyramids grow epitaxially from the substrate.

19. A composition as claimed in claim 17 or 18 in which said graphene layer is up to 20 nm in thickness.

20. A composition as claimed in any of claims 17-19 in which said masking layer comprises a metal oxide, metal nitride or metal fluoride.

21. A composition as claimed in any of claims 17-20 in which said masking layer comprises Al₂O₃, W₂O₃, HfO₂, TiO₂, MoO₂, SiO₂, AlN, BN (e.g. h-BN), Si₃N₄, MgF₂ or CaF₂.

22. A composition as claimed in any of claims 17-21 in which the substrate comprises sapphire, especially sapphire (0001).

23. A composition as claimed in any of claims 17-22 in which said nanowires or nanopyramids are doped.

24. A composition as claimed in any of claims 17-23 in which said nanowires or nanopyramids are axially heterostructured.

25. A composition as claimed in any of claims 17-24 in which said nanowires or nanopyramids are core-shell or radially heterostructured.

26. A composition as claimed in any of claims 17-25 wherein a graphitic top contact layer or conventional metal contact or metal stack contact layer is present on top of said nanowires or nanopyramids.

27. A composition as claimed in any of claims 17-26 wherein the holes in the graphene layer are smaller than the holes in the masking layer so that a portion of the graphene layer is exposed during nanowire or nanopyramid growth.

28. A composition as claimed in any of claims 17 to 27 wherein the surface of the graphene layer is chemically/physically modified in the said plurality of holes in masking layer to enhance the epitaxial growth of nanowires or nanopyramids or to modify its electrical properties.

29. A composition as claimed in any preceding claim, wherein the graphene layer is in electrical contact with at least a portion of said nanowires or nanopyramids.

30. A process comprising:
(I) obtaining a composition of matter in which a graphene layer is carried directly on a group III-V intermediate layer, wherein said intermediate layer is carried directly on a sapphire, Si, SiC, Ga₂O₃ or group III-V semiconductor substrate;
(II) etching a plurality of holes through said graphene layer; and
(III) growing a plurality of nanowires or nanopyramids from said intermediate layer in said holes, said nanowires or nanopyramids comprising at least one semiconducting group III-V compound.

31. A process as claimed in claim 30 in which said nanowires or nanopyramids are grown in the presence or absence of a catalyst.

32. A product obtained by a process as claimed in claim 30 or 31.

33. A device, such as an opto-electronic device, comprising a composition as claimed in claims 1 to 16, e.g. a solar cell, photodetector or LED.

34. A process comprising:
(I) providing a graphene layer carried on a sapphire, Si, SiC, Ga₂O₃ or group III-V semiconductor substrate;
(II) depositing an oxide, nitride or fluoride masking layer on said graphene layer;
(III) introducing a plurality of holes in said masking layer and graphene layer, said holes penetrating through to said substrate; and
(IV) growing a plurality of semiconducting group III-V nanowires or nanopyramids in the holes, preferably via molecular beam epitaxy or metal organic vapour phase epitaxy.

35. A process as claimed in claim 34 in which said nanowires or nanopyramids are grown in the presence or absence of a catalyst.

36. A product obtained by a process as claimed in claim 34 or 35.

37. A device, such as an opto-electronic device, comprising a composition as claimed in claims 17 to 29, e.g. a solar cell, photodetector or LED.

38. A process comprising:
(I) obtaining a composition of matter in which a graphene layer is carried directly on a sapphire, Si, SiC, Ga₂O₃ or group III-V semiconductor substrate;
(II) etching a plurality of holes through said graphene layer; and
(III) growing a plurality of nanowires or nanopyramids from said substrate in said holes, said nanowires or nanopyramids comprising at least one semiconducting group III-V compound.

39. A process as claimed in claim 38 in which said nanowires or nanopyramids are grown in the presence or absence of a catalyst.

40. A product obtained by a process as claimed in claim 38 or 39.

41. A device, such as an opto-electronic device, comprising a composition as claimed in claims 2 to 16, e.g. a solar cell, photodetector or LED.
